(19) United States
(12) Patent Application Publication
(10) Pub. No.: US 2026/0321320 A1
(43) Pub. Date: Oct. 15, 2026

(54) MEMORY SYSTEMS AND OPERATING METHODS THEREOF, MEMORY DEVICES, AND STORAGE MEDIA

(71) Applicant: Yangtze Memory Technologies Co., Ltd., Wuhan (CN)

(72) Inventor: Yonggang Chen, Wuhan (CN)

(21) Appl. No.: 19/287,412

(22) Filed: Jul. 31, 2025

(30) Foreign Application Priority Data
Apr. 10, 2025 (CN) 202510447692.2

(51) Int. Cl. G11C 16/28; G11C 16/30; G11C 16/34

(52) U.S. Cl. CPC G11C 16/28; G11C 16/30; G11C 16/34

(57) ABSTRACT

A disclosed memory system includes a memory device and a memory controller coupled to the memory device. The memory device includes a memory cell. The memory controller is configured to: send a first read instruction to the memory device, wherein the first read instruction indicates to the memory device to perform first read operations on a plurality of target memory cells based on a set of first read voltages, to obtain a first read result; send a second read instruction to the memory device, wherein the second read instruction indicates to the memory device to perform second read operations on the plurality of target memory cells based on a set of second read voltages, to obtain a second read result; and determine a threshold voltage distribution of the plurality of target memory cells based on the first and second read results.

### CROSS-REFERENCE TO RELATED APPLICATIONS

This application claims priority to and the benefit of Chinese Patent Application 202510447692.2, filed on Apr. 10, 2025, which is hereby incorporated by reference in its entirety.

### TECHNICAL FIELD

The present disclosure relates to the field of storage technology, and particularly to memory systems and operating methods thereof, memory devices, and storage media.

### BACKGROUND

With the development of storage technology, the application of memory devices is becoming increasingly widespread. For example, memory devices are used in devices such as mobile phones and computers, etc. At present, there are many scenarios in which determining a threshold voltage distribution of a plurality of memory cells in a memory device is required.

### BRIEF DESCRIPTION OF THE DRAWINGS

In order to provide a clearer explanation of the technical solution in examples of the present disclosure, a brief introduction will be given below to the drawings required for the description of the examples. It is apparent that the drawings described below are only some examples of the present disclosure. For those skilled in the art, other drawings may be obtained from these drawings.

FIG. 1 is a schematic structural diagram of an electronic system provided in an example of the present disclosure.

FIG. 2 is a schematic structural diagram of a memory card provided in an example of the present disclosure.

FIG. 3 is a schematic structural diagram of a solid-state drive provided in an example of the present disclosure.

FIG. 4 is a schematic structural diagram of a memory device provided in an example of the present disclosure.

FIG. 5 is a partial cross-sectional view of a memory array including a memory string provided in an example of the present disclosure.

FIG. 6 is a schematic structural diagram of a peripheral circuit provided in an example of the present disclosure.

FIG. 7 is a schematic structural diagram of a memory system provided in an example of the present disclosure.

FIG. 8 is a schematic diagram of a standard threshold voltage distribution of memory cells provided in an example of the present disclosure.

FIG. 9 is a schematic diagram for determining a target voltage interval provided in an example of the present disclosure.

FIG. 10 is another schematic diagram for determining a target voltage interval provided in an example of the present disclosure.

FIG. 11 is a schematic structural diagram of another memory device provided in an example of the present disclosure.

FIG. 12 is a schematic structural diagram of another memory system provided in an example of the present disclosure.

FIG. 13 is a flowchart of a method for operating a memory system provided in an example of the present disclosure.

FIG. 14 is a flowchart of another method for operating a memory system provided in an example of the present disclosure.

FIG. 15 is a flowchart of another method for operating a memory system provided in an example of the present disclosure.

FIG. 16 is a flowchart of another method for operating a memory system provided in an example of the present disclosure.

FIG. 17 is a flowchart of another method for operating a memory system provided in an example of the present disclosure.

FIG. 18 is a flowchart of another method for operating a memory system provided in an example of the present disclosure.

### DETAILED DESCRIPTION

In order to clarify the purpose, technical solution, and advantages of the present disclosure, a further detailed description of examples of the present disclosure will be provided below in conjunction with the accompanying drawings. Although examples of the present disclosure are shown in the accompanying drawings, it should be understood that the present disclosure may be implemented in various forms and should not be limited by examples described herein. On the contrary, providing these examples is to enable a more thorough understanding of the present disclosure and to fully convey the scope of the present disclosure to those skilled in the art. The accompanying drawings are all in a very simplified form and use imprecise proportions, only for the convenience and clarity of illustrating the purpose of examples of the present disclosure.

It should be noted that the terms “first”, “second”, etc. used in the present disclosure are intended to distinguish similar objects and do not necessarily describe a specific order or sequence. It should be understood that data used in such a way may be interchanged in appropriate circumstances, so that examples described herein may be implemented in order other than those illustrated or described herein. The examples described in the following examples do not represent all examples consistent with the present disclosure. On the contrary, they are only examples consistent with some aspects of the present disclosure.

It should be easy to understand that the meanings of “on”, “above”, and “over” in the present disclosure should be interpreted in the widest way, so that “on” not only means “directly on” something, but also includes the meaning of “on” something with intermediate features or layers in between, and “above” or “over” not only means “above” or “over” something, but may also include the meaning of “above” or “over” something without intermediate features or layers in between (e.g., directly on something).

In addition, spatial relative terms such as “below”, “under”, “lower”, “above”, “upper”, etc. may be used herein to describe the relationship between one element or feature and another element(s) or feature(s) as shown in the figures for ease of description. The spatial relative terms aim to encompass different orientations in use or operation of a device in addition to those depicted in the figures. The device may be oriented in other ways (rotated 90 degrees or in other orientations), and the spatial relative descriptors used herein may also be explained accordingly.

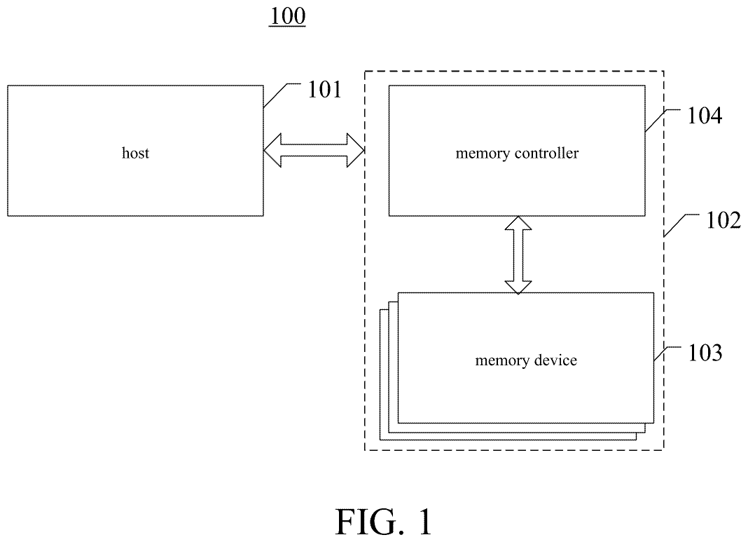

FIG. 1 shows a schematic diagram of an electronic system provided in an example of the present disclosure. The electronic system 100 may be a mobile phone, desktop computer, laptop computer, tablet computer, vehicle computer, game console, printer, positioning device, wearable electronic device, smart sensor, virtual reality (VR) device, augmented reality (AR) device, or any other suitable electronic device with a storage device.

As shown in FIG. 1, the electronic system 100 includes a host 101 and a memory system 102 coupled to the host 101. The host 101 may be a processor of an electronic device, such as Central Processing Unit (CPU) or a System on Chip (SoC), such as Application Processor (AP). The host 101 may be configured to send data to the memory system 102. Alternatively, the host 101 may be configured to receive data from the memory system 102.

The memory system 102 includes one or more memory devices 103 and a memory controller 104. The memory controller 104 is coupled to the memory device 103, and is configured to control the memory device 103. The memory device 103 may be any type of memory. Optionally, the memory device 103 is a NAND (Not AND) flash memory, such as 3D NAND flash memory. Alternatively, the memory device 103 is a Dynamic Random Access Memory (DRAM) or the like.

For example, the memory controller 104 is also coupled to the host 101. The memory controller 104 may manage data stored in the memory device 103 and communicate with the host 101.

In one example, the memory controller 104 is designed to operate in low duty cycle environments, such as Secure Digital (SD) cards, Compact Flash (CF) cards, Universal Serial Bus (USB) flash drives, or other media used in electronic devices such as personal calculators, digital cameras, mobile phones, etc.

In one example, the memory controller 104 is designed to operate in high duty cycle environments, such as Solid State Disk (SSD) or Embedded Multi Media Card (eMMC). SSD or eMMC is used as data storage for mobile devices such as smartphones, tablets, laptops, etc., and an enterprise memory array.

The memory controller 104 may be configured to control operations of the memory device 103, such as reading, erasing, and programming operations. The memory controller 104 may also be configured to manage various functions related to data stored or to be stored in the memory device 103, including but not limited to bad block management, garbage collection, logical to physical address translation, wear leveling, etc. In one example, the memory controller 104 is also configured to process error correction codes (ECC) for data read from or written to the memory device 103.

The memory controller 104 may also perform any other suitable function, such as formatting the memory device 103. The memory controller 104 may communicate with external devices (such as the host 101) according to a specific communication protocol. For example, the memory controller 104 may communicate with external devices through at least one of various interface protocols, such as USB protocol, Multi Media Card (MMC) protocol, Peripheral Component Interconnect (PCI) protocol, PCI Express (PCI-E) protocol, Advanced Technology Attachment (ATA) protocol, Serial ATA protocol (SATA), Parallel ATA protocol, Small Computer Small Interface (SCSI) protocol, Enhanced Small Drive Interface (ESDI) protocol, Integrated Drive Electronics (IDE) protocol, Firewire protocol, Non-Volatile Memory express (NVMe) protocol, etc.

The memory controller 104 and one or more memory devices 103 may be integrated into various types of memory systems 102, such as being included in the same package (e.g., Universal Flash Storage (UFS) package or eMMC package). That is to say, the memory system 102 may be implemented and packaged into different types of terminal electronic products.

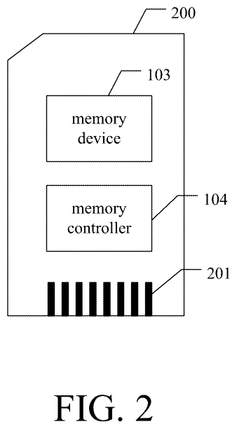

For example, as shown in FIG. 2, the memory controller 104 and a single memory device 103 may be integrated into the memory card 200. The memory card 200 may include a PC (Personal Computer Memory Card International Association, PCMCIA, abbreviated as PC) card, CF card, Smart Media (SM) card, memory stick, multimedia card (MMC, Reduced Size MMC (RS-MMC)), MMCmicro, SD card (SD, miniSD, microSD), Secure Digital High Capacity (SDHC), UFS, etc. The memory card 200 may also include a memory card connector 201 that couples the memory card 200 to a host (e.g., host 101 in FIG. 1).

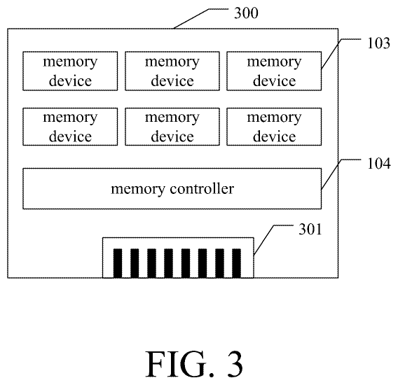

For example, as shown in FIG. 3, the memory controller 104 and a plurality of memory devices 103 may be integrated into a solid-state drive (also known as a solid-state disk (SSD)) 300. The solid-state drive 300 may also include a solid-state drive connector 301 that couples the solid-state drive 300 with a host (e.g., host 101 in FIG. 1). In one example, storage capacity and/or operating speed of the solid-state drive 300 is greater than that of the memory card 200.

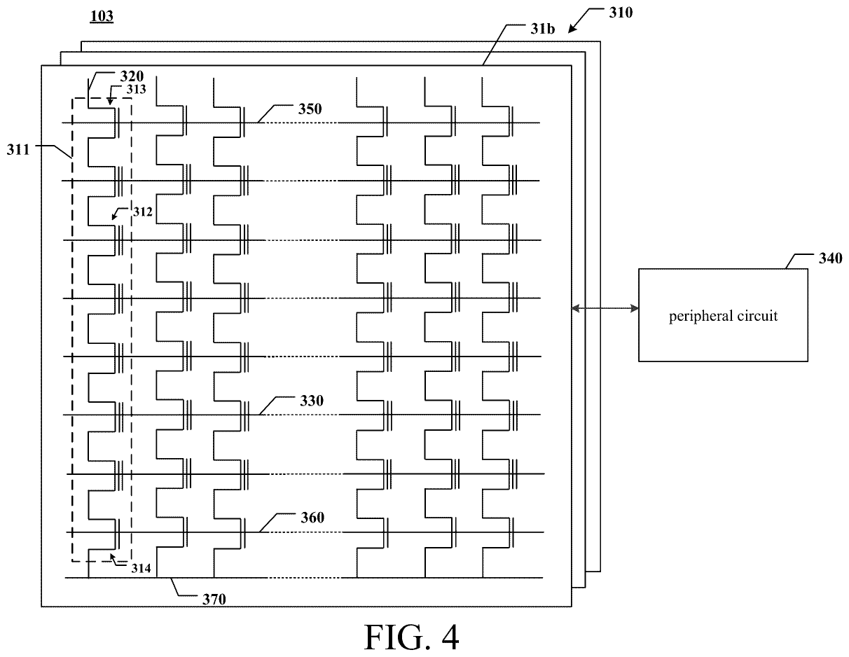

FIG. 4 shows a schematic diagram of a memory device provided in an example of the present disclosure. As shown in FIG. 4, the memory device 103 includes a memory array 310 and a peripheral circuit 340 coupled to the memory array 310.

The memory array 310 includes a plurality of memory strings 311 arranged in an array form, which are located on a support side of a substrate (not shown) and extend in a direction perpendicular to a substrate support surface. For example, the substrate support surface refers to a surface of the substrate used to support the memory array 310.

Each memory string 311 includes a plurality of memory cells 312, and the plurality of memory cells 312 in each memory string 311 are stacked in a direction perpendicular to the substrate support surface. Each memory cell 312 has a function of storing data, and the stored data is determined by the number of electrons stored in the memory cell 312, which may determine a threshold voltage of the memory cell 312. Therefore, the threshold voltage of the memory cell 312 may indicate data stored in the memory cell 312. The memory cell 312 is a floating gate field-effect transistor or a charge trap type field-effect transistor.

For example, the memory cell 312 may be a Single Level Cell (SLC), Multi Level Cell (MLC), Triple Level Cell (TLC), or Quad Level Cell (QLC), among others. The SLC, MLC, TLC, and QLC are capable of storing 1-bit, 2-bit, 3-bit, and 4-bit data, respectively.

Each memory string 311 also includes an upper select transistor 313 and a lower select transistor 314. The upper select transistors 313 in different memory strings 311, which are at the same or similar height from the substrate support surface, are coupled to the same drain select line (DSL) 350. The lower select transistors 314 in different memory strings 311, which are at the same or similar height from the substrate support surface, are coupled to the same source select line (SSL) 360. The upper select transistor 313 and the lower select transistor 314 are used to activate a selected memory string when reading, programming, or erasing memory cells. The upper select transistor 313 is also known as a Top Select Gate (TSG), and the lower select transistor 314 is also known as a Bottom Select Gate (BSG). For example, there is also a dummy cell (DC) between the upper select transistor 313 and the memory cell 312, and between the lower select transistor 314 and the memory cell 312.

One end of the memory string 311 is coupled to the bit line (BL) 320, and the other end of the memory string 311 is coupled to the source line (SL) 370.

The memory cells 312 in different memory strings 311, which are at the same or similar height from the substrate support surface, are located on the same layer. A plurality of memory cells 312 in the same layer constitute a memory cell layer, that is, the memory array 310 includes a plurality of memory cell layers, and a plurality of word lines 330 are coupled to a plurality of memory cell layers, respectively.

All memory strings 311 in the memory array 310 that share the same set of word lines constitute a memory block 31b. Each memory block 31b includes a plurality of memory pages. A memory page is the smallest unit for reading and programming (also known as writing), and the memory block 31b is the smallest unit for erasing.

In some examples, source terminals of the respective memory strings 311 in the same memory block 31b are all coupled to the same source line 370, also known as a Common Source Line (CSL). In other words, the respective memory strings 311 in the same memory block 31b have an Array Common Source (ACS). A source terminal of the memory string 311 refers to one end of the memory string 311 used for coupling with the source line 370.

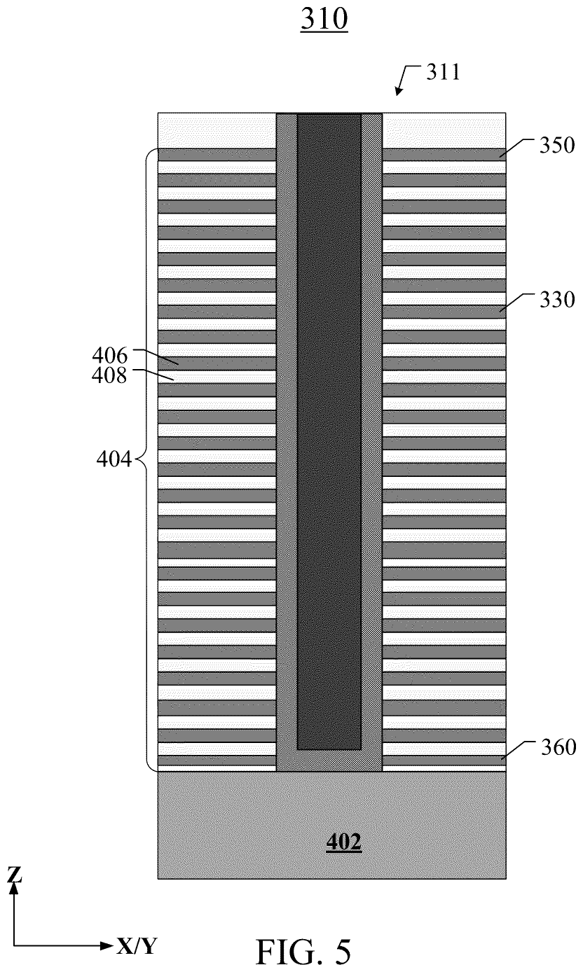

FIG. 5 shows a partial cross-sectional view of a memory array including a memory string provided according to the present disclosure. As shown in FIG. 5, the memory array 310 includes a memory string 311, which may extend vertically through the storage stack 404 above the substrate 402. The substrate 402 may include silicon (e.g., monocrystalline silicon), silicon germanium (SiGe), gallium arsenide (GaAs), germanium (Ge), silicon on insulator (SOI), germanium on insulator (GOI), or any other suitable material.

The storage stack 404 may include alternating gate conductive layers 406 and gate to gate dielectric layers 408. The number of pairs of gate conductive layer 406 and gate to gate dielectric layer 408 in storage stack 404 may determine the number of the memory cells 312 in the memory string 311.

The gate conductive layer 406 may include a conductive material, including but not limited to tungsten (W), cobalt (Co), copper (Cu), aluminum (Al), polycrystalline silicon, doped silicon, silicide, or any combination thereof. In some examples, each gate conductive layer 406 includes a metal layer, such as a tungsten layer. In some examples, each gate conductive layer 406 includes a doped polycrystalline silicon layer. Each gate conductive layer 406 may include a gate (also known as a control gate) surpassing the memory cell 312, and may extend laterally as a drain select line 350 at the top of the storage stack 404, as a source select line 360 at the bottom of the storage stack 404, or extend laterally between the drain select line 350 and the source select line 360 as a word line 330.

It should be understood that although not shown in FIG. 5, additional components of the memory array 310 may be formed, including but not limited to gate line gaps/source contacts, local contacts, interconnect layers, etc.

Continuing with reference to FIG. 4, the peripheral circuit 340 may be coupled to the memory array 310 through the drain select line 350, the source select line 360, the bit line 320, the source line 370, and the word line 330. The peripheral circuit 340 may include any suitable analog, digital, and mixed signal circuit for facilitating operations of the memory array 310 by applying a voltage and/or current signal to the memory cell 312 through the drain select line 350, the source select line 360, the bit line 320, the source line 370, and the word line 330, and sensing the voltage and/or current signal from the memory cell 312.

The peripheral circuit 340 may include various types of peripheral circuits formed using Metal Oxide Semiconductor (MOS) technology. The peripheral circuit 340 may control the memory cells 312 in the selected memory string 311 by controlling a voltage of the word line 330 coupled to the selected memory string 311 and a voltage of the bit line 320 coupled to the selected memory string 311, so as to achieve operations such as erasing, programming, reading, or verifying, etc.

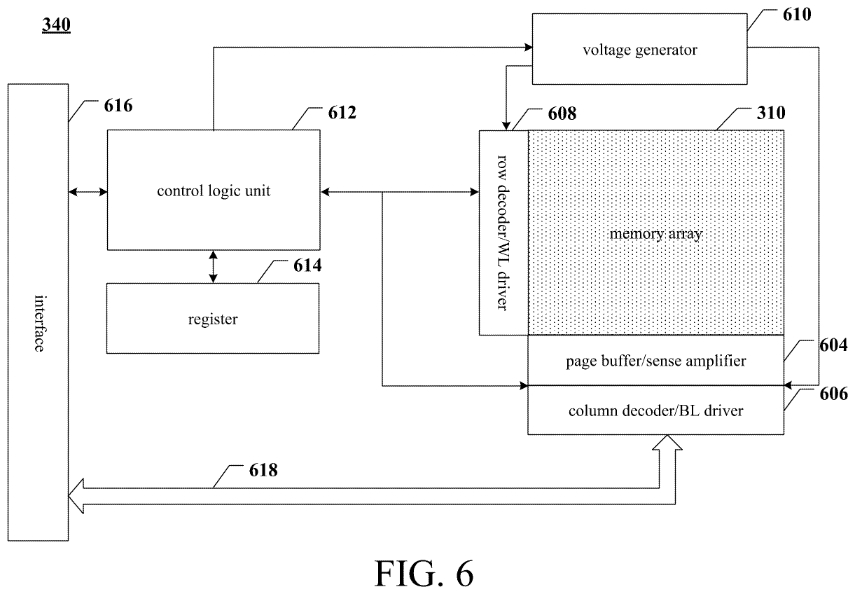

For example, FIG. 6 shows an example structure of the peripheral circuit 340. The peripheral circuit 340 includes the page buffer/sense amplifier 604, the column decoder/bit line (BL) driver 606, the row decoder/word line (WL) driver 608, the voltage generator 610, the control logic unit 612, the register 614, the interface 616, and the data bus 618. It should be understood that in some examples, the peripheral circuit 340 may also include additional components not shown in FIG. 6.

The page buffer/sense amplifier 604 may be configured to read data from the memory array 310 and program (write) data to the memory array 310 based on a control signal from the control logic unit 612. In one example, the page buffer/sense amplifier 604 may store programming data (write data) to be programmed into the memory array 310. In another example, the page buffer/sense amplifier 604 may perform a program verification operation to ensure that data has been correctly programmed into the memory cell 312 coupled to a selected word line 330. In yet another example, the page buffer/sense amplifier 604 may also sense low-power signals representing data bits stored in the memory cell 312 from the bit line 320, and amplify small voltage swings to recognizable logic levels during a read operation.

The column decoder/bit line driver 606 may be configured to be controlled by the control logic unit 612 and select one or more memory strings 311 by applying a bit line voltage generated from the voltage generator 610.

The row decoder/word line driver 608 may be configured to be controlled by the control logic unit 612 and select/deselect the word line 330 of the memory block 31b of the memory array 310. The row decoder/word line driver 608 may also be configured to use a word line voltage generated from the voltage generator 610 to drive the word line 330. In some examples, the row decoder/word line driver 608 may also select/deselect and drive the drain select line 350 and the source select line 360.

The voltage generator 610 may be configured to be controlled by the control logic unit 612 and generate word line voltages (such as read voltage, programming voltage, pass voltage, local voltage, verification voltage, etc.), bit line voltages, and source line voltages to be supplied to the memory array 310.

The control logic unit 612 may be coupled to each peripheral circuit component described above and configured to control operations of each peripheral circuit component. In an example, a control logic of control logic unit 612 may be determined by firmware in the memory device 103.

The register 614 may be coupled to the control logic unit 612 and includes a status register, a command register, and an address register for storing status information, command opcodes (OP codes), and command addresses used to control operations of each peripheral circuit component.

The interface 616 may be coupled to the control logic unit 612 and serve as a control buffer to buffer control commands received from a host (not shown) and relay them to the control logic unit 612, and buffer status information received from the control logic unit 612 and relay it to the host. The interface 616 may also be coupled to the column decoder/bit line driver 606 via the data bus 618 and serve as a data I/O (Input/Output) interface and data buffer to buffer data and relay or buffer data to the memory array 310, or relay or buffer data from the memory array 310.

In some examples, the number of interfaces 616 may be a plurality of, and the plurality of interfaces 616 may include a power connection interface specifically designed for connecting to a power supply. The power supply is coupled to the memory device 103 through the power connection interface, thereby providing power to the memory device 103.

With the development of storage technology, the application of memory devices is becoming increasingly widespread. For example, memory devices are used in devices such as mobile phones and computers, etc. At present, there are many scenarios that require determining a threshold voltage (Vt) distribution of memory cells in a memory device (such as NAND flash memory).

The threshold voltage distribution of memory cells refers to a distribution of threshold voltages of the memory cells. A threshold voltage of a memory cell refers to the minimum voltage value required for the memory cell to transition from one stable state to another or for the memory cell to be able to reliably identify its memory state. In simply terms, a threshold voltage of a memory cell is a critical voltage limit that distinguishes different memory states of the memory cell.

For example, for NAND flash memory, a memory cell is a transistor with a storage layer (floating gate or charge trapping layer) located between the gate and channel of the transistor, surpassed by an insulating layer, and may capture and retain electrons. When electrons are stored on the storage layer, the conduction characteristics of the transistor will be affected. Based on this, for NAND flash memory, the threshold voltage of the memory cell refers to the minimum voltage that causes the transistor to start conducting when a voltage is applied to the gate of the transistor. Different numbers of electrons on the storage layer may cause changes in the threshold voltage of the transistor. For example, when there are more electrons on the storage layer, the threshold voltage will increase. When there are few or no electrons on the storage layer, the threshold voltage will decrease. By detecting the magnitude of the threshold voltage, data stored in the memory cell may be determined.

In some examples, the application scenario of determining the threshold voltage distribution of memory cells may include: by monitoring the threshold voltage distribution of memory cells during the manufacturing process of memory devices, timely detecting process deviations, ensuring consistency in product quality and performance. For example, if the threshold voltage distribution of a batch of memory devices is abnormal, it may indicate that there are problems in the photolithography, doping and other process steps, and process parameters need to be adjusted timely.

In some other examples, the application scenario of determining the threshold voltage distribution of memory cells may also include: designers may optimize circuit structures of memory cells based on the actual threshold voltage distribution, and improving the performance and reliability of memory devices. For example, if the threshold voltage distribution is wide, redundant design or fault-tolerant circuits may be used to improve the stability of memory devices.

In some other examples, the application scenario of determining the threshold voltage distribution of memory cells may also include: quickly locating the cause of faults or errors by analyzing the threshold voltage distribution, and finding out potential factors that cause memory device to fail or the information stored in the memory cells to be erroneous.

In some other examples, the application scenario of determining the threshold voltage distribution of memory cells may also include knowing the characteristics of the memory device by determining the threshold voltage distribution of the memory cell during the testing process of the memory device.

In some other examples, the application scenario of determining the threshold voltage distribution of memory cells may also include: determining whether to re-determine the read voltage from the threshold voltage distribution of the memory cells. For example, if the threshold voltage distribution of the memory cells deviates, it is required to re-determine the read voltage from a valley voltage corresponding to the threshold voltage distribution to increase the read accuracy and improve system performance.

In one example, the process of determining the threshold voltage distribution of memory cells is implemented through a plurality of measurement operations, wherein each measurement operation is performed based on one measurement voltage. The efficiency of determining the threshold voltage distribution of memory cells is relatively low. In addition, the correlation between a measurement voltage on which one measurement operation is based and a normal read voltage of a memory device (such as NAND flash memory) is weak. After determining the threshold voltage distribution of memory cells, it is usually required to make later corrections to the threshold voltage distribution of the memory cells before further use (such as for analyzing the reasons for errors in the information stored in the memory cells), which is inefficient. In other words, in one example, the way of measuring and determining the threshold voltage distribution of the memory cells by moving a single measurement point each time is slow in speed and low in efficiency. In addition, the position of the single measurement point often requires later correction before further use.

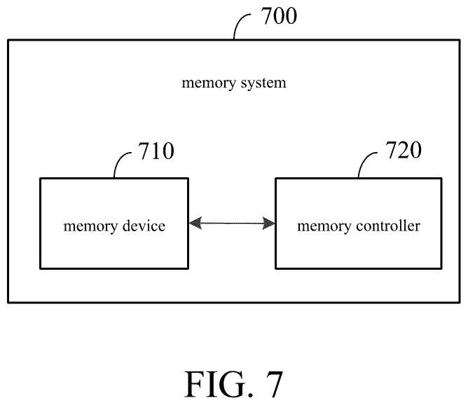

An example of the present disclosure provides a memory system, as shown in FIG. 7, which includes a memory device 710 and a memory controller 720 coupled to the memory device 710. The memory device 710 includes a memory cell. The memory system 700 may be the memory system 102 shown in FIG. 1, the memory device 710 may be the memory device 103 shown in FIGS. 1 to 4, and the memory controller 720 may be the memory controller 104 shown in FIGS. 1 to 3.

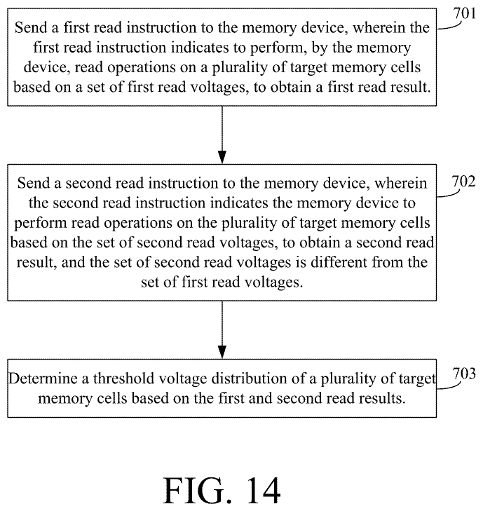

In the example of the present disclosure, the memory controller 720 is configured to perform operations 701 to 703 (refer to FIG. 14) as follows:

Operation 701: send a first read instruction to the memory device 710, wherein the first read instruction indicates to perform, by the memory device 710, read operations on a plurality of target memory cells based on a set of first read voltages, to obtain a first read result.

The first read instruction is a read instruction sent from the memory controller 720 to the memory device 710 for causing the memory device 710 to perform a pass of read operations. In this pass of read operations, the memory device 710 is to perform read operations on a plurality of target memory cells based on the set of first read voltages.

The plurality of target memory cells are a plurality of memory cells in the memory device 710 for which a threshold voltage distribution is to be determined. In some examples, the first read instruction carries address information, and the memory device 710 may determine a plurality of target memory cells from the address information. For example, the memory device 710 decodes address information to obtain row and column addresses, and takes a plurality of memory cells determined from the row and column addresses as a plurality of target memory cells. In some examples, the memory device 710 includes a plurality of memory blocks. After decoding the address information, the memory device 710 may also obtain a memory block address. The memory device 710 takes a memory block identified by the memory block address as a target memory block, and then determines a plurality of target memory cells in the target memory block from the row and column addresses.

The example of the present disclosure does not limit the number of a plurality of target memory cells and the positions of a plurality of target memory cells of all memory cells of the memory device 710, and may be flexibly set or adjusted according to the application scenario. For example, a plurality of target memory cells may include memory cells in one or more memory cell layers of a target memory block. The target memory block is determined from a memory block address indicated in the address information carried by the first read instruction. The one or more memory cell layers are determined from the row addresses indicated in the address information carried by the first read instruction. In this case, the column addresses indicated in the address information carried by the first read instruction are the column addresses corresponding to all memory cells in the memory cell layer.

In the example of the present disclosure, a memory cell in the memory device 710 is a memory cell capable of storing at least two bits of data. For example, the type of the memory cell in the memory device 710 may be MLC, TLC, QLC, etc.

The set of first read voltages is a combination of a plurality of first read voltages, that is, the set of first read voltages includes a plurality of first read voltages. The plurality of first read voltages in the set of first read voltages are a set of pre-set voltage values which the memory device 710 performs read operations on a plurality of target memory cells based on.

In some examples, the first read instruction carries a set of first read voltages, and the memory device 710 may parse the set of first read voltages from the first read instruction after receiving the first read instruction.

In some other examples, the first read instruction carries first indication information, which indicates a way of determining the set of first read voltages. After receiving the first read instruction, the memory device 710 parses the first indication information from the first read instruction and then determines the set of first read voltages from the way of determining indicated in the first indication information.

For example, the set of first read voltages is obtained by offsetting a reference read voltage in a set of reference read voltages. The way of determining indicated in the first indication information may be an offset way for offsetting the reference read voltage in the set of reference read voltages. The memory device 710 records the reference read voltage in the set of reference read voltages and after determining the offset way from the first indication information, offset the reference read voltage in the set of reference read voltages with the determined offset way, to obtain the set of first read voltages. For example, the number of first read voltages in the set of first read voltages is the same as the number of reference read voltages in the set of reference read voltages.

The set of reference read voltages is a combination of a plurality of reference read voltages, and the plurality of reference read voltages in the set of reference read voltages are read voltages based on which data stored in memory cells of the memory device 710 are read by default. In some examples, reference read voltages in the set of reference read voltages may be determined from a standard threshold voltage distribution of memory cells in the memory device 710. The standard threshold voltage distribution of memory cells refers to the distribution of threshold voltages of the memory cells in an ideal situation. In the ideal situation, threshold voltages of memory cells storing different data are different, and a plurality of reference read voltages in the set of reference read voltages may be the read voltages that better distinguish the threshold voltages of the memory cells storing different data.

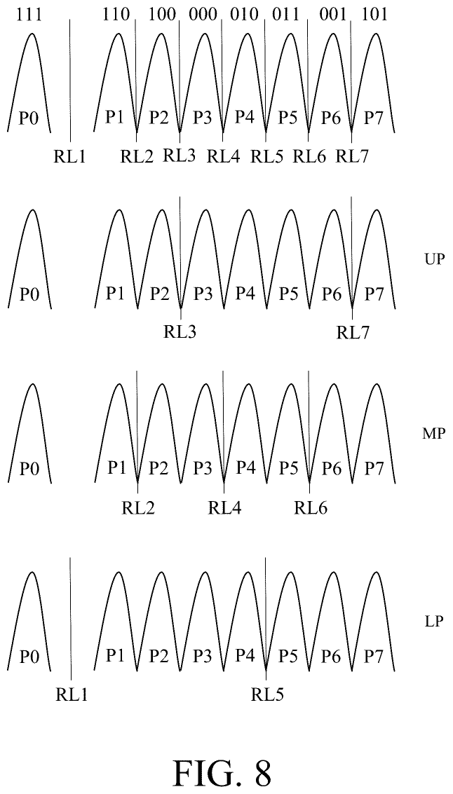

For example, taking TLC as the type of memory cells in memory device 710, a schematic diagram of a standard threshold voltage distribution of the memory cells may be seen in FIG. 8. The memory cells in the memory device 710 may be programmed (or erased) to be in one of eight states represented by P0 to P7. Different states correspond to different 3-bit data, and the mapping between states and corresponding 3-bit data may vary. In FIG. 8, the 3-bit data corresponding to the 8 states P0 to P7 are “111”, “110”, “100”, “000”, “010”, “011”, “001”, and “101”, respectively.

Referring to FIG. 8, threshold voltages of memory cells in different states (e.g., memory cells storing different data) are within voltage ranges corresponding to different peaks. The respective reference read voltages in the set of reference read voltages are set between adjacent peaks to better distinguish the threshold voltages of memory cells storing different data. The number of reference read voltages in the set of reference read voltages is 7, and these 7 reference read voltages are RL1, RL2, RL3, RL4, RL5, RL6, and RL7 in ascending order.

For example, when the type of memory cells is TLC, the 3-bit data stored in the memory cells includes data corresponding to three memory pages respectively, namely low page (LP), middle page (MP), and up page (UP). The data corresponding to LP is low bit data in 3-bit data, the data corresponding to MP is middle bit data in 3-bit data, and the data corresponding to UP is high bit data in 3-bit data. According to RL1 and RL5, data corresponding to LP may be read; according to RL2, RL4, and RL6, data corresponding to MP may be read; and according to RL3 and RL7, data corresponding to UP may be read.

After obtaining the set of first read voltages, the memory device 710 performs read operations on a plurality of target memory cells based on the set of first read voltages to obtain the first read result. The first read result refers to the result obtained by performing read operations on a plurality of target memory cells based on the set of first read voltages. The first read result includes first data corresponding to each target memory cell, which refers to data stored in each target memory cell read from the respective first read voltages in the set of first read voltages.

For example, the basic principle of the memory device 710 performing read operations on a plurality of target memory cells based on the set of first read voltages to obtain the first read result includes that the memory device 710 applies a first read voltage in the set of first read voltages to a target word line, and determines the first data corresponding to a target memory cell coupled to the target word line from the conduction state of the target memory cell coupled to the target word line. The target word line is any one of word lines coupled to the plurality of target memory cells, and the number of target memory cells coupled to the target word line may be one or more. The number of word lines coupled to the plurality of target memory cells may be one or more. For the case where the number of word lines coupled to the plurality of target memory cells is more than one, according to the above principle, the first data corresponding to the target memory cells coupled to respective word lines is determined respectively, to obtain the first read result.

In some examples, each target memory cell is capable of storing k bits of data, wherein k is an integer greater than 1. In this case, the first data corresponding to each target memory cell includes k first sub data, each of which is 1-bit data. The set of first read voltages includes first read voltages corresponding to k memory pages respectively, and different memory pages correspond to different first read voltages. The k first sub data correspond one-to-one with k memory pages, that is, the j-th first sub data in the k first sub data is obtained by reading from the first read voltage corresponding to the j-th memory page in the k memory pages, wherein j is a positive integer less than or equal to k. For example, taking TLC as the type of target memory cells, each target memory cell may store 3 bits of data. The first data corresponding to each target memory cell includes 3 first sub data, and the set of first read voltages includes first read voltages corresponding to 3 memory pages (the first memory page is LP, the second memory page is MP, and the third memory page is UP) respectively. The 1^{st} first sub data of the 3 first sub data corresponding to each target memory cell is obtained by reading from the first read voltage corresponding to LP, the 2^{nd} first sub data of the 3 first sub data corresponding to each target memory cell is obtained by reading from the first read voltage corresponding to MP, and the 3^{rd} first sub data of the 3 first sub data corresponding to each target memory cell is obtained by reading the first read voltage corresponding to UP.

In some examples, the process of the memory device 710 performing read operations on a plurality of target memory cells based on the set of first read voltages to obtain the first read result includes: the memory device 710 applying the first read voltage corresponding to the j-th memory page in the k memory pages to a target word line, and obtaining the j-th first sub data in the k first sub data corresponding to a target memory cell coupled to the target word line, wherein j is a positive integer less than or equal to k. For example, for each target memory cell coupled to the target word line, the j-th first sub data in the k first sub data corresponding to the target memory cell may be determined from the conduction state of the target memory cell after the memory device 710 applies the first read voltage corresponding to the j-th memory page to the target word line. The conduction state of the target memory cell may be determined from a response from the target memory cell, such as changes in the current and voltage of bit line coupled to the target memory cell, etc. The order of applying first read voltages corresponding to different memory pages to the target word line may be set according to experience or flexibly adjusted according to requirements.

It should be noted that for the case that the number of the plurality of first read voltages corresponding to the j-th memory page are one than more, applying first read voltages corresponding to the j-th memory page to the target word line refers to sequentially applying respective first read voltages corresponding to the j-th memory page to the target word line. After each first read voltage corresponding to the j-th memory page is applied to the target word line, the conduction state of the target memory cell may be recorded. Finally, considering the conduction state after applying respective first read voltages corresponding to the j-th memory page to the target word line, the j-th first sub data in the k first sub data corresponding to the target memory cell is determined. The sequence of applying respective first read voltages corresponding to the j-th memory page to the target word line may be set according to experience or flexibly adjusted according to requirements. For example, respective first read voltages corresponding to the j-th memory page are applied to the target word line in ascending order.

In some examples, before applying a first read voltage corresponding to a memory page to a target word line each time, a target bit line in the memory device 710 may be charged to a preset voltage, so as to determine the conduction state of the target memory cell coupled to the target word line from changes in voltage on the target bit line after applying the first read voltage corresponding to the memory page to the target word line. The target bit line refers to a bit line to which the target memory cell coupled to the target word line is coupled, and the number of target bit lines may be one or more.

Taking TLC as the type of target memory cells, the set of first read voltages includes the first read voltages corresponding to LP (RL1′ and RL5′), the first read voltages corresponding to MP (RL2′, RL4′, and RL6′), and the first read voltages corresponding to UP (RL3′ and RL7′). RL1′, RL2′, RL3′, RL4′, RL5′, RL6′, and RL7′ are obtained by offsetting RL1, RL2, RL3, RL4, RL5, RL6, and RL7 in the set of reference read voltages, respectively. The process of the memory device 710 performing read operations on a plurality of target memory cells based on the set of first read voltages to obtain the first read result includes: charging the target bit line in the memory device 710 to a preset voltage, sequentially applying RL1′ and RL5′ to the target word line, and determining the 1^{st} first sub data (e.g., low bit data) in the 3 first sub data corresponding to the target memory cell coupled to the target word line from the conduction state of the target memory cell coupled to the target word line after applying a voltage every time. For example, the low-bit data corresponding to the target memory cell which is not turned on after applying RL1′ is 1; The low bit data corresponding to the target memory cell that is not turned on after applying RL1′ but is turned on after applying RL5′ is 0; The low bit data corresponding to the target memory cell that is not turned on after applying RL5′ is 1.

Recharge the target bit line in the memory device 710 to the preset voltage, and sequentially apply RL2′, RL4′, and RL6′ to the target word line, and determine the 2^{nd} first sub data (e.g., middle bit data) in the 3 first sub data corresponding to the target memory cell coupled to the target word line from the conduction state of the target memory cell coupled to the target word line after applying a voltage every time. For example, the middle bit data corresponding to the target memory cell that is turned on after applying RL2′ is 1; The middle bit data corresponding to the target memory cell that is not turned on after applying RL2′ but turned on after applying RL4′ is 0; The middle bit data corresponding to the target memory cell that is not turned on after applying RL4′ but is turned on after applying RL6′ is 1; The middle bit data corresponding to the target memory cell that is not turned on after applying RL6′ is 0.

Recharge the target bit line in the memory device 710 to the preset voltage, and sequentially apply RL3′ and RL7′ to the target word line, and determine the 3^{rd} first sub data (e.g., high bit data) in the 3 first sub data corresponding to the target memory cell coupled to the target word line from the conduction state of the target memory cell coupled to the target word line after applying a voltage every time. For example, the high bit data corresponding to the target memory cell that is turned on after applying RL3′ is 1; The high bit data corresponding to the target memory cell that is not turned on after applying RL3′ but turned on after applying RL7′ is 0; The high bit data corresponding to the target memory cell that is not turned on after applying RL7′ is 1.

After determining the low, middle, and high bit data corresponding to the target memory cell coupled to the target word line, the first data corresponding to the target memory cell coupled to the target word line may be obtained. After traversing all the word lines coupled to a plurality of target memory cells, the first data corresponding to all target memory cells may be obtained, in order to obtain the first read result.

In the example of the present disclosure, the memory device 710 sends the first read result to the memory controller 720 after obtaining the first read result, and the memory controller 720 receives the first read result.

For example, the memory device 710 includes a peripheral circuit and a memory array, wherein the memory array comprises a memory cell. The memory controller 720 sending the first read instruction to the memory device 710 refers to the memory controller 720 sending the first read instruction to a peripheral circuit in the memory device 710. After receiving the first read instruction, the peripheral circuit in the memory device 710 determines a set of first read voltages and a plurality of target memory cells from the first read instruction, and then performs read operations on the plurality of target memory cells based on the set of first read voltages to obtain the first read result. After obtaining the first read result, the peripheral circuit sends the first read result to the memory controller 720.

Operation 702: Send a second read instruction to the memory device 710, wherein the second read instruction indicates the memory device 710 to perform read operations on the plurality of target memory cells based on the set of second read voltages, to obtain a second read result, and the set of second read voltages is different from the set of first read voltages.

The second read instruction is a read instruction sent from the memory controller 720 to the memory device 710 for causing the memory device 710 to perform another pass of read operations, in which the memory device 710 is to perform read operations on the plurality of target memory cells based on the set of second read voltages. That is to say, multiple passes of read operations of the example of the present disclosure is performed for memory cells with the same address (e.g., a plurality of target memory cells).

For example, the second read instruction carries address information of a plurality of target memory cells, and the memory device 710 may determine the plurality of target memory cells by decoding the address information.

For example, the second read instruction does not carry address information, and the memory device 710 may perform read operations on the same a plurality of target memory cells as the first read instruction according to the second read instruction in default.

The set of second read voltages is a combination of a plurality of second read voltages, that is, the set of second read voltages includes a plurality of second read voltages. The plurality of second read voltages in the set of second read voltages are a set of pre-set voltage values which the memory device 710 performs read operations on a plurality of target memory cells based on. The set of second read voltages different from the set of first read voltages indicates that a plurality of second read voltages in the set of second read voltages are not completely identical to a plurality of first read voltages in the set of first read voltages. In some examples, the number of second read voltages in the set of second read voltages is the same as the number of first read voltages in the set of first read voltages.

In some examples, the second read instruction carries a set of second read voltages, and the memory device 710 may parse the set of second read voltages from the second read instruction after receiving the second read instruction.

In some other examples, the second read instruction carries second indication information which indicates the way of determining of the set of second read voltages. After receiving the second read instruction, the memory device 710 parses the second indication information from the second read instruction and determines the set of second read voltages according to the way of determining indicated by the second indication information.

For example, the set of second read voltages is obtained by offsetting reference read voltages in the set of reference read voltages, and the way of determining indicated by the second indication information may be an offset way for offsetting reference read voltages in the set of reference read voltages. The memory device 710 may record the reference read voltages in the set of reference read voltages, and after determining the offset way from the second indication information, offset the reference read voltages in the set of reference read voltages with the determined offset way to obtain the set of second read voltages. For example, the number of second read voltages in the set of second read voltages is the same as the number of reference read voltages in the set of reference read voltage.

The example of the present disclosure does not limit the timing at which the memory controller 720 sends the second read instruction to the memory device 710. In some examples, the memory controller 720 sends a second read instruction to the memory device 710 when an interval between the current time and the time at which the first read instruction is sent to the memory device 710 reaches an interval threshold. The interval threshold may be set according to experience or flexibly adjusted according to requirements. In some other examples, the memory controller 720 sends a second read instruction to the memory device 710 upon receiving the first read result sent from the memory device 710. In some other examples, the memory controller 720 sends a second read instruction to the memory device 710 while sending a first read instruction to the memory device 710. In other words, the memory controller 720 sends a read instruction to the memory device 710, the read instruction includes a first read instruction and a second read instruction.

After receiving the second read instruction, the memory device 710 performs read operations on a plurality of target memory cells based on the set of second read voltages to obtain the second read result. The second read result includes second data corresponding to the plurality of target memory cells, and the second data corresponding to each target memory cell refers to data stored in each target memory cell read according to respective second read voltages in the set of second read voltages.

The principle of the memory device 710 performing read operations on a plurality of target memory cells based on the set of second read voltages is the same as the principle of the memory device 710 performing read operations on a plurality of target memory cells based on the set of first read voltages, and will not be repeated here.

After obtaining the second read result, the memory device 710 sends the second read result to the memory controller 720, and the memory controller 720 receives the second read result.

In some examples, the set of first read voltages and the set of second read voltages are any two sets of read voltages in n sets of read voltages, wherein n is an integer greater than 1. The n sets of read voltages include a set of reference read voltages and (n−1) sets of offset read voltages. Different sets of offset read voltages in the (n−1) sets of offset read voltages are obtained by offsetting reference read voltages in the set of reference read voltages with different offset ways.

The value of n may be set according to experience or flexibly adjusted according to requirements, which is not limited in examples of the present disclosure. The set of first read voltages and the set of second read voltages are any two sets of read voltages in the n sets of read voltages. In some examples, one set of the set of first read voltages and the set of second read voltages is the set of reference read voltages, and the other is any one set of offset read voltages in the (n−1) sets of offset read voltages. In some other examples, the set of first read voltages and the set of second read voltages are any two sets of offset read voltages in the (n−1) sets of offset read voltages.

The set of reference read voltages refers to a combination of a plurality of reference read voltages, and the set of offset read voltages is obtained by offsetting reference read voltages in the set of reference read voltages. Different sets of offset read voltages is obtained by offsetting reference read voltages in the set of reference read voltages with different offset ways. Each set of offset read voltages includes a plurality of offset read voltages, and the number of offset read voltages in each set of offset read voltages is the same as the number of reference read voltages in the set of reference read voltages.

The offset way with which any set of offset read voltages is obtained by offsetting reference read voltages in the set of reference read voltages is called as the offset way corresponding to any set of offset read voltages. That is to say, different sets of offset read voltages in (n−1) sets of offset read voltages correspond to different offset ways. Based on this, although the (n−1) sets of offset read voltages are all determined on the basis of the same set of reference read voltages, the (n−1) sets of offset read voltages are different with each other. For example, different sets of offset read voltages may be different indicates that at least one different offset read voltage may exist in different sets of offset read voltages.

In some examples, the offset way corresponding to any set of offset read voltages includes an offset direction and an offset value. In other words, any set of offset read voltages is obtained by offsetting reference read voltages in the set of reference read voltages by an offset value corresponding to the any set of offset read voltages in an offset direction corresponding to the any set of offset read voltages. The offset direction is a first offset direction or a second offset direction. The first offset direction is a direction of increasing a reference read voltage in the set of reference read voltages, and the second offset direction is a direction of decreasing a reference read voltage in the set of reference read voltages.

For example, different sets of offset read voltages corresponding to different offset ways may refer to different sets of offset read voltages corresponding to different offset directions, different sets of offset read voltages corresponding to different offset values, or different sets of offset read voltages corresponding to different offset ways and different offset values.

In some examples, a plurality of sets of offset read voltages corresponding to the same offset value in (n−1) sets of offset read voltages correspond to different offset directions, and a plurality of sets of offset read voltages corresponding to the same offset direction in (n−1) sets of offset read voltages correspond to different offset values. In other words, if a plurality of sets of offset read voltages correspond to the same offset value, the offset directions corresponding to the plurality of sets of offset read voltages are different, to ensure that the offset ways corresponding to the plurality of sets of offset read voltages are different, thereby ensuring that the plurality of sets of offset read voltages are different with each other. If a plurality of sets of offset read voltages correspond to the same offset direction, the offset values corresponding to the plurality of sets of offset read voltages are different, to ensure that the offset ways corresponding to the plurality of sets of offset read voltages are different, thereby ensuring that the plurality of sets of offset read voltages are different with each other.

The law of the offset ways corresponding to (n−1) sets of offset read voltages may be set according to experience or flexibly adjusted according to requirements, which is not limited in examples of the present disclosure. Next, an example explanation will be given on the law of the offset ways corresponding to the (n−1) sets of offset read voltages.

In some examples, the law of the offset ways corresponding to (n−1) sets of offset read voltages may be as follows: an offset direction and an offset value corresponding to the i-th set of offset read voltages in the (n−1) sets of offset read voltages are a first offset direction and a first offset value, respectively, wherein i is a positive odd number less than or equal to n−3; an offset direction and an offset value corresponding to the (i+1)th set of offset read voltages in the (n−1) sets of offset read voltages are a second offset direction and the first offset value, respectively; and an offset direction and an offset value corresponding to the (i+2)th set of offset read voltages in the (n−1) sets of offset read voltages are the first offset direction and a second offset value, respectively, wherein the first offset direction is a direction of increasing a reference read voltage in the set of reference read voltages, and the second offset direction is a direction of decreasing a reference read voltage in the set of reference read voltages, and the second offset value is greater than the first offset value.

In other words, the law of the offset ways corresponding to the (n−1) sets of offset read voltages mentioned above may be understood as follows: on the basis of arranging the (n−1) sets of offset read voltages in order from the first set of offset read voltages to the (n−1)th set of offset read voltages, two adjacent sets of offset read voltages in the (n−1) sets of offset read voltages correspond to different offset directions; If a plurality of sets of offset read voltages in the (n−1) sets of offset read voltage correspond to the same offset direction, the offset value corresponding to the set of offset read voltages arranged later is greater than the offset value corresponding to the set of offset read voltages arranged earlier.

For example, for any two adjacent sets of offset read voltages in the plurality of sets of offset read voltages corresponding to the same offset direction in the (n−1) sets of offset read voltages, the difference between the offset values corresponding to the any two adjacent sets of offset read voltages may be set according to experience or flexibly adjusted according to requirements, which is not limited in examples of the present disclosure. For example, the difference between the offset values corresponding to the any two adjacent sets of offset read voltages may be 1V, or 2V, etc.

In some examples, the law of the offset ways corresponding to the (n−1) sets of offset read voltages may also be referred to as bidirectional offset and offset values may be gradually increased. According to the law of such offset ways, it is beneficial to improve the efficiency of determining the final threshold voltage distribution.

Taking i=1 and n=6 as an example, based on the law of the offset ways corresponding to the (n−1) sets of offset read voltages mentioned above, the way of determining respective sets of offset read voltages is as follows: increasing respective reference read voltages in the set of reference read voltages by 1V to obtain the 1^{st} set of offset read voltages; decreasing respective reference read voltages in the set of reference read voltages by 1V to obtain the 2^{nd} set of offset read voltages; increasing respective reference read voltages in the set of reference read voltages by 2V to obtain the 3^{rd} set of offset read voltages; decreasing respective reference read voltages in the set of reference read voltages by 2V to obtain the 4th set of offset read voltages; increasing respective reference read voltages in the set of reference read voltages by 3V to obtain the 5^{th} set of offset read voltages; and decreasing respective reference read voltages in the set of reference read voltages by 3V to obtain the 6^{th} set of offset read voltages.

For example, the offset way corresponding to the 1^{st} set of offset read voltages may be represented as +1, the offset way corresponding to the 2^{nd} set of offset read voltages may be represented as −1, the offset way corresponding to the 3^{rd} set of offset read voltages may be represented as +2, the offset way corresponding to the 4^{th} set of offset read voltages may be represented as −2, the offset way corresponding to the 5^{th} set of offset read voltages may be represented as +3, and the offset way corresponding to the 6^{th} set of offset read voltages may be represented as −3. “+” represents the offset direction is a direction of increasing a reference read voltage in the set of reference read voltages, “−” represents the offset direction is a direction of decreasing a reference read voltage in the set of reference read voltages, “1” represents the offset value corresponding to one step, “2” represents the offset value corresponding to two steps, and “3” represents the offset value corresponding to three steps. The example of the present disclosure takes the offset value of 1V corresponding to one step as an example, but the offset value corresponding to one step may also be other numerical values.

In some examples, based on the law of the offset ways corresponding to the (n−1) sets of offset read voltages mentioned above, the termination condition for the (n−1) sets of offset read voltages may be determined as follows: an offset direction and an offset value corresponding to the (n−2)th set of offset read voltages in the (n−1) sets of offset read voltages are the first offset direction and a target offset value, respectively; and an offset direction and an offset value corresponding to the (n−1)th set of offset read voltages in the (n−1) sets of offset read voltages are the second offset direction and the target offset value, respectively, wherein the target offset value is an offset value which causes an offset read voltage corresponding to a first reference read voltage to be greater than or equal to an offset read voltage corresponding to a second reference read voltage, the offset read voltage corresponding to the first reference read voltage is obtained by offsetting the first reference read voltage in the first offset direction, and the offset read voltage corresponding to the second reference read voltage is obtained by offsetting the second reference read voltage in the second offset direction; and the first reference read voltage and the second reference read voltage are two adjacent reference read voltages in the set of reference read voltages in order of magnitude, and the first reference read voltage is less than the second reference read voltage.

In other words, in the case that the law of the offset ways corresponding to the (n−1) sets of offset read voltages is bidirectional offset and offset values may be gradually increased, the termination condition for the (n−1) sets of offset read voltages is determined as follows: a voltage (the offset read voltage corresponding to the first reference read voltage) obtained by increasing A voltage (the first reference read voltage) is greater than or equal to a voltage (the offset read voltage corresponding to the second reference read voltage) obtained by decreasing B voltage (the second reference read voltage), wherein A voltage and B voltage are two adjacent reference read voltages in the set of reference read voltages, and A voltage is less than B voltage. On the basis of determining the termination condition for the (n−1) sets of offset read voltages, read operations may be stopped timely on the basis of ensuring that the determined (n−1) sets of offset read voltages cover various voltages comprehensively, so as to improve the efficiency of determining the threshold voltage distribution on the basis of ensuring the accuracy of the determined threshold voltage distribution.

It should be noted that a first reference read voltage and a second reference read voltage may constitute a pair of reference voltages, that is, a pair of reference voltages includes two adjacent reference read voltages in the set of reference read voltages in order of magnitude. In the process of determining whether the termination condition for determining the (n−1) sets of offset read voltages have been met, only one pair of reference voltages may be used, or a plurality of pairs of reference voltages may be used. In the case of using a plurality of pairs of reference voltages to determine whether the termination condition for determining the (n−1) sets of offset read voltages has been met, the target offset value is an offset value which causes the offset read voltage corresponding to the first reference read voltage in each pair of reference voltages to be greater than or equal to the offset read voltage corresponding to the second reference read voltage in the pair of reference voltages.

It should be further noted that the law of the offset ways corresponding to the (n−1) sets of offset read voltages described above is only an example, and examples of the present disclosure are not limited thereto. The offset way corresponding to the (n−1) sets of offset read voltages may also have other laws, such as the following law 1 or law 2.

Law 1: an offset direction and an offset value corresponding to the i-th set of offset read voltages in the (n−1) sets of offset read voltages are the second offset direction and a third offset value, respectively, wherein i is a positive odd number less than or equal to n−3; an offset direction and an offset value corresponding to the (i+1)th set of offset read voltages in the (n−1) sets of offset read voltages are the first offset direction and a third offset value, respectively; and an offset direction and an offset value corresponding to the (i+2)th set of offset read voltages in the (n−1) sets of offset read voltages are the second offset direction and a fourth offset value, respectively, wherein the fourth offset value is greater than the third offset value.

Under Law 1, the termination condition for the (n−1) sets of offset read voltages may be determined as follows: an offset direction and an offset value corresponding to the (n−2)th set of offset read voltages in the (n−1) sets of offset read voltages are the second offset direction and a reference offset value, respectively; and an offset direction and an offset value corresponding to the (n−1)th set of offset read voltages in the (n−1) sets of offset read voltages are the first offset direction and the reference offset value, respectively, wherein the reference offset value is an offset value which causes the offset read voltage corresponding to the third reference read voltage to be less than or equal to the offset read voltage corresponding to the fourth reference read voltage, and the offset read voltage corresponding to the third reference read voltage is obtained by offsetting the third reference read voltage in the second offset direction, and the offset read voltage corresponding to the fourth reference read voltage is obtained by offsetting the fourth reference read voltage in the first offset direction, the third reference read voltage and the fourth reference read voltage are two adjacent reference read voltages in the set of reference read voltages in order of magnitude, and the third reference read voltage is greater than the fourth reference read voltage.

Law 2: n−1 is an even number, and the offset direction corresponding to the i-th set of offset read voltages is different from the offset direction corresponding to the

$$( \frac{n - 1}{2} + i )$$

th set of offset read voltages, and the offset value corresponding to the i-th set of offset read voltages is the same as the offset value corresponding to the

$$( \frac{n - 1}{2} + i )$$

th set of offset read voltages; respective sets of offset read voltages from the i-th set of offset read voltages to the

$$( \frac{n - 1}{2} )$$

th set or offset read voltages correspond to the same offset direction, but correspond to offset values incremented sequentially, wherein i is an integer not less than

$$\frac{n - 1}{2} .$$

Under Law 2, the termination condition for the (n−1) sets of offset read voltages may be determined as follows: an offset direction and an offset value corresponding to the

$$( \frac{n - 1}{2} )$$

th set of offset read voltages in the (n−1) sets of offset read voltages are the first offset direction and the target offset value, respectively; and an offset direction and an offset value corresponding to the (n−1)th set of offset read voltages in the (n−1) sets of offset read voltages are the second offset direction and the target offset value, respectively, wherein the target offset value is an offset value which causes the offset read voltage corresponding to the first reference read voltage to be greater than or equal to the offset read voltage corresponding to the second reference read voltage. Alternatively, the termination condition for the (n−1) sets of offset read voltages may be determined as follows: an offset direction and an offset value corresponding to the

$$( \frac{n - 1}{2} )$$

th set of offset read voltages in the (n−1) sets of offset read voltages are the second offset direction and the reference offset value, respectively; and an offset direction and an offset value corresponding to the (n−1)th set of offset read voltages in the (n−1) sets of offset read voltages are the first offset direction and the reference offset value, respectively, wherein the reference offset value is an offset value which causes the offset read voltage corresponding to the third reference read voltage to be less than or equal to the offset read voltage corresponding to the fourth reference read voltage.

Operation 703: Determine a threshold voltage distribution of a plurality of target memory cells based on the first and second read results.

The first read result is a read result of a plurality of target memory cells determined from performing read operations with the set of first read voltages, and the second read result is a read result of a plurality of target memory cells determined from performing read operations with the set of second read voltages. After receiving the first and second read results, the memory controller 720 determines the threshold voltage distribution of a plurality of target memory cells by comprehensively considering the first and second read results. The threshold voltage distribution of a plurality of target memory cells refers to a statistical distribution characteristic presented by threshold voltages of respective target memory cells.

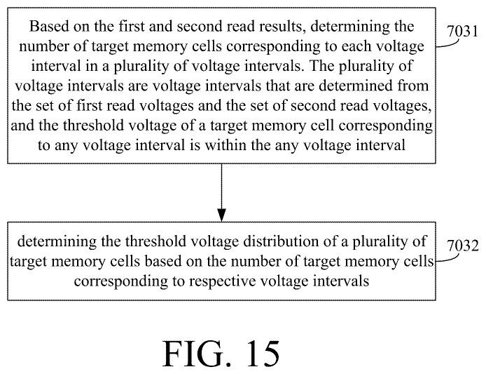

In some examples, the process of the memory controller 720 determining the threshold voltage distribution of a plurality of target memory cells based on the first and second read results includes the following operations 7031 and 7032 (refer to FIG. 15):

Operation 7031: Based on the first and second read results, determining the number of target memory cells corresponding to each voltage interval in a plurality of voltage intervals. The plurality of voltage intervals are voltage intervals that are determined from the set of first read voltages and the set of second read voltages, and the threshold voltage of a target memory cell corresponding to any voltage interval is within the any voltage interval.

The plurality of voltage intervals are voltage intervals directly utilized for determining the threshold voltage distribution of a plurality of target memory cells. Each voltage interval has a lower limit and an upper limit, wherein the lower limit of each voltage interval refers to the minimum voltage value in each voltage interval, and the upper limit of each voltage interval refers to the maximum voltage value in each voltage interval.

The plurality of voltage intervals are voltage intervals that are determined based on the set of first read voltages and the set of second read voltages. For example, respective first read voltages in the set of first read voltages and respective second read voltages in the set of second read voltages are arranged in ascending order, and a plurality of voltage intervals are determined from the arranged voltages. The plurality of voltage intervals may include voltage intervals that are not greater than the minimum voltage in the arranged voltages, voltage intervals composed of every two adjacent voltages in the arranged voltages, and voltage intervals that are not less than the maximum voltage in the arranged voltages.

Before determining the threshold voltage distribution of a plurality of target memory cells, it is required to first determine the number of target memory cells corresponding to each voltage interval, and the threshold voltage of the target memory cell corresponding to any voltage interval should be within the any voltage interval. For example, the threshold voltage of the target memory cell within the any voltage interval indicates that the threshold voltage of the target memory cell is not less than the lower limit of the any voltage interval and not greater than the upper limit of the any voltage interval.

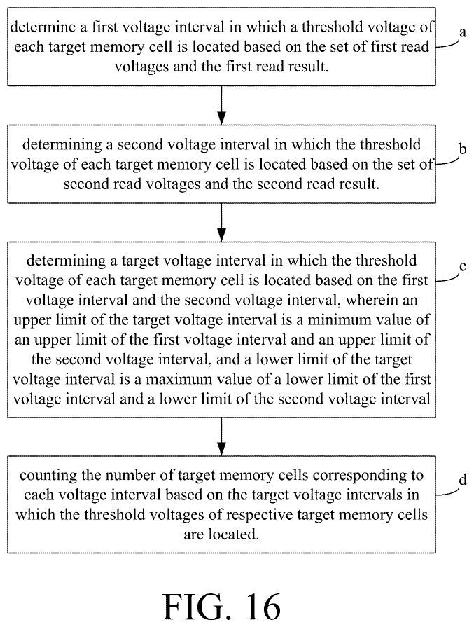

In some examples, the process of the memory controller 720 determining the number of target memory cells corresponding to each voltage interval based on the first and second read results includes the following operations a to operations d (refer to FIG. 16):

Operation a: determine a first voltage interval in which a threshold voltage of each target memory cell is located based on the set of first read voltages and the first read result.

For example, the first read result includes first data corresponding to each target memory cell. The process of performing read operations on a plurality of target memory cells based on the set of first read voltages is a process of determining the first data corresponding to each target memory cell from the magnitude relationship between the threshold voltage of each target memory cell and respective first read voltages in the set of first read voltages. Therefore, the magnitude relationship between the threshold voltage of each target memory cell and respective first read voltages in the set of first read voltages may be determined from the first data corresponding to each target memory cell, and then the first voltage interval in which the threshold voltage of each target memory cell is located may be determined.

For example, the first voltage interval in which the threshold voltage of each target memory cell is located may be a voltage interval that is not greater than the minimum first read voltage in the set of first read voltages, or a voltage interval that is not less than the maximum first read voltage in the set of first read voltages, or a voltage interval composed of any two adjacent first read voltages in the set of first read voltages in order of magnitude.

For example, taking TLC as the type of target memory cells, respective first read voltages in the set of first read voltages are RL1′, RL2′, RL3′, RL4′, RL5′, RL6′, and RL7′ in ascending order. For each target memory cell, if the first data corresponding to the target memory cell is 111, the first voltage interval in which the threshold voltage of the target memory cell is located is (−∞, RL1′]; if the first data corresponding to the target memory cell is 110, the first voltage interval in which the threshold voltage of the target memory cell is located is [RL1′, RL2′]; If the first data corresponding to the target memory cell is 100, the first voltage interval in which the threshold voltage of the target memory cell is located is [RL2′, RL3′]; If the first data corresponding to the target memory cell is 000, the first voltage interval in which the threshold voltage of the target memory cell is located is [RL3′, RL4′]; If the first data corresponding to the target memory cell is 010, the first voltage interval in which the threshold voltage of the target memory cell is located is [RL4′, RL5′]; If the first data corresponding to the target memory cell is 011, the first voltage interval in which the threshold voltage of the target memory cell is located is [RL5′, RL6′]; If the first data corresponding to the target memory cell is 001, the first voltage interval in which the threshold voltage of the target memory cell is located is [RL6′, RL7′]; If the first data corresponding to the target memory cell is 101, then the first voltage interval in which the threshold voltage of the target memory cell is located is [RL7′,+∞).

Operation b: determining a second voltage interval in which the threshold voltage of each target memory cell is located based on the set of second read voltages and the second read result.

For example, the second read result includes second data corresponding to each target memory cell. The process of performing read operations on a plurality of target memory cells based on the set of second read voltages is a process of determining the second data corresponding to each target memory cell from the magnitude relationship between the threshold voltage of each target memory cell and respective second read voltages in the set of second read voltages. Therefore, the magnitude relationship between the threshold voltage of each target memory cell and respective second read voltages in the set of second read voltages may be determined from the second data corresponding to each target memory cell, and then the second voltage interval in which the threshold voltage of each target memory cell is located may be determined.

For example, the second voltage interval in which the threshold voltage of each target memory cell is located may be a voltage interval that is not greater than the minimum second read voltage in the set of second read voltages, or a voltage interval that is not less than the maximum second read voltage in the set of second read voltages, or a voltage interval composed of any two adjacent second read voltages in the set of second read voltages in order of magnitude.

For example, taking TLC as the type of target memory cells, respective second read voltages in the set of second read voltages are RL1″, RL2″, RL3″, RL4″, RL5″, RL6″, and RL7″ in ascending order. For each target memory cell, if the second data corresponding to the target memory cell is 111, the second voltage interval in which the threshold voltage of the target memory cell is located is (−∞, RL1″]; if the second data corresponding to the target memory cell is 110, the second voltage interval in which the threshold voltage of the target memory cell is located is [RL1″, RL2″]; If the second data corresponding to the target memory cell is 100, the second voltage interval in which the threshold voltage of the target memory cell is located is [RL2″, RL3″]; If the second data corresponding to the target memory cell is 000, the second voltage interval in which the threshold voltage of the target memory cell is located is [RL3″, RL4″]; If the second data corresponding to the target memory cell is 010, the second voltage interval in which the threshold voltage of the target memory cell is located is [RL4″, RL5″]; If the second data corresponding to the target memory cell is 011, the second voltage interval in which the threshold voltage of the target memory cell is located is [RL5″, RL6″]; If the second data corresponding to the target memory cell is 001, the second voltage interval in which the threshold voltage of the target memory cell is located is [RL6″, RL7″]; If the second data corresponding to the target memory cell is 101, then the second voltage interval in which the threshold voltage of the target memory cell is located is [RL7″, +∞).

Operation c: determining a target voltage interval in which the threshold voltage of each target memory cell is located based on the first voltage interval and the second voltage interval, wherein an upper limit of the target voltage interval is a minimum value of an upper limit of the first voltage interval and an upper limit of the second voltage interval, and a lower limit of the target voltage interval is a maximum value of a lower limit of the first voltage interval and a lower limit of the second voltage interval.

After determining the first voltage interval and the second voltage interval, determining the minimum value of the upper limit of the first voltage interval and the upper limit of the second voltage interval, and the maximum value of the lower limit of the first voltage interval and the lower limit of the second voltage interval, and then, taking the determined minimum value as the upper limit of the target voltage interval and the determined maximum value as the lower limit of the target voltage interval to obtain the target voltage interval in which the threshold voltage of each target memory cell is located. In other words, an intersection interval between the first voltage interval and the second voltage interval is taken as the target voltage interval in which the threshold voltage of each target memory cell is located.

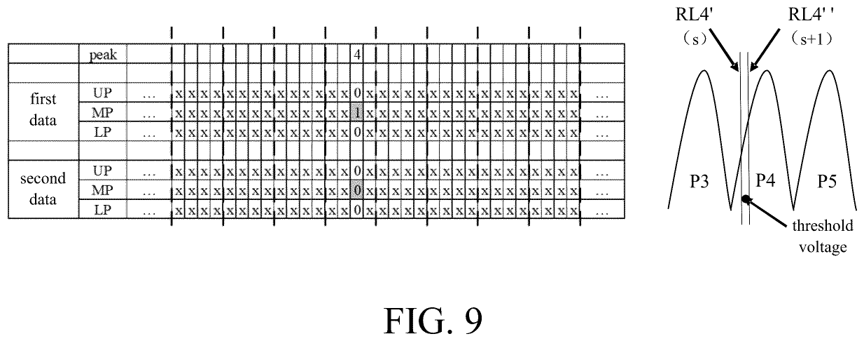

For example, referring to FIG. 9, taking TLC as the type of target memory cells, the set of first read voltages is obtained by increasing respective reference read voltages in the set of reference read voltages by an offset value (represented as s) corresponding to s amplitudes, respectively, and the set of second read voltages is obtained by increasing respective reference read voltages in the set of reference read voltages by an offset value (represented as s+1) corresponding to (s+1) amplitudes, respectively, wherein s is a positive integer. If a target memory cell corresponds to a peak corresponding to the P4 state in the standard threshold voltage distribution, and the first data corresponding to the target memory cell is 010, and the second data corresponding to the target memory cell is 000, then the first voltage interval in which the threshold voltage of the target memory cell is located is [RL4′, RL5′], and the second voltage interval in which the threshold voltage of the target memory cell is located is [RL3″, RL4″], wherein RL4′ is less than RL4″. If RL4′ is greater than RL3″, and RL5′ is greater than RL4″, the target voltage interval in which the threshold voltage of the target memory cell is located is [RL4′, RL4″].

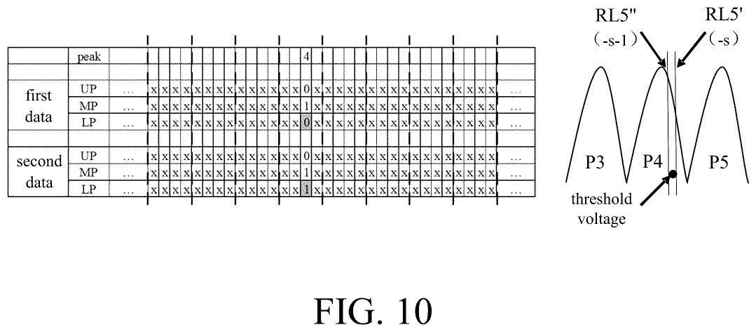

For example, referring to FIG. 10, taking TLC as the type of target memory cells, the set of first read voltages is obtained by decreasing respective reference read voltages in the set of reference read voltages by an offset value (represented as −s) corresponding to s amplitudes, respectively, and the set of second read voltages is obtained by decreasing respective reference read voltages in the set of reference read voltages by an offset value (represented as −s−1) corresponding to (s+1) amplitudes, respectively, wherein s is a positive integer. If a target memory cell corresponds to a peak corresponding to the P4 state in the standard threshold voltage distribution, and the first data corresponding to the target memory cell is 010 and the second data corresponding to the target memory cell is 011, then the first voltage interval in which the threshold voltage of the target memory cell is located is [RL4′, RL5′], and the second voltage interval in which the threshold voltage of the target memory cell is located is [RL5″, RL6″], wherein RL5′ is greater than RL5″. If RL4′ is less than RL5″, and RL5′ is less than RL6″, then the target voltage interval in which the threshold voltage of the target memory cell is located is [RL5″, RL5′].

Operation d: counting the number of target memory cells corresponding to each voltage interval based on the target voltage intervals in which the threshold voltages of respective target memory cells are located.

The target voltage interval in which the threshold voltage of each target memory cell is located is one voltage interval of a plurality of voltage intervals. The number of target memory cells corresponding to each voltage interval in a plurality of voltage intervals may be counted according to the target voltage intervals in which the threshold voltages of respective target memory cells are located. The number of target memory cells corresponding to any voltage interval may be 0, or one or more.

It should be noted that operations a to operations d described above are only examples by determining the number of target memory cells corresponding to each voltage interval only based on the first and second read results, and examples of the present disclosure are not limited thereto.

In some examples, the example way of determining the number of target memory cells corresponding to each voltage interval based on the first and second read results may also include: determining the number of target memory cells corresponding to each voltage interval in a plurality of voltage intervals based on the first read result, the second read result, and other read results, wherein the other read results are read results that are obtained based on read operations performed on a plurality of target memory cells with other sets of read voltages in n sets of read voltages except for the set of first read voltages and the set of second read voltages. The examples of the present disclosure do not limit the order of obtaining the first read result, the second read result, and other read results. The plurality of voltage intervals are determined based on respective read voltages in n sets of read voltages. The plurality of voltage intervals include voltage intervals that are not greater than the minimum read voltage of respective read voltages in the n sets of read voltages, voltage intervals composed of every two adjacent read voltages in respective read voltages in the n sets of read voltages in order of magnitude, and voltage intervals that are not less than the maximum read voltage of respective read voltages in the n sets of read voltages.

In an example, a voltage interval in which the threshold voltage of each target memory cell is located may be determined based on each read result of the first read result, the second read result, and other read results, and then, the determined minimum value of the upper limits of respective voltage intervals is taken as the upper limit of the target voltage interval in which the threshold voltage of each target memory cell is located, and the determined maximum value of the lower limits of respective voltage intervals is taken as the lower limit of the target voltage interval in which the threshold voltage of each target memory cell is located, and the target voltage interval in which the threshold voltage of each target memory cell is located is obtained. Then, the number of target memory cells corresponding to each voltage interval in a plurality of voltage intervals is counted according to the target voltage interval in which the threshold voltage of each target memory cell is located. The threshold voltage of the target memory cell corresponding to any voltage interval is within the any voltage interval.

The example way of determining the target voltage interval in which the threshold voltage of each target memory cell is located based on the first read result, the second read result, and other read results is not limited in examples of the present disclosure. In some examples, an intermediate voltage interval is determined from two voltage intervals determined from the first two obtained read results, in an order of obtaining the first read result, the second read result, and other read results. The updated intermediate voltage interval is determined from the intermediate voltage interval and a voltage interval determined based on the third obtained read result. The re-updated intermediate voltage interval is determined from the updated intermediate voltage interval and a voltage interval determined based on the fourth obtained read result, and so on, until the currently determined intermediate voltage interval is determined from a voltage interval determined based on the last obtained read result, and the currently determined intermediate voltage interval is taken as the target voltage interval. The principle of obtaining another voltage interval from two voltage intervals is: taking the minimum value of the upper limits of the two voltage intervals as the upper limit of the other voltage interval, and taking the maximum value of the lower limits of the two voltage intervals as the lower limit of the other voltage interval.

Operation 7032: determining the threshold voltage distribution of a plurality of target memory cells based on the number of target memory cells corresponding to respective voltage intervals.

In some examples, the process of determining the threshold voltage distribution of a plurality of target memory cells based on the number of target memory cells corresponding to respective voltage intervals includes: constructing a histogram according to respective voltage intervals and the number of target memory cells corresponding to respective voltage intervals, and determining the threshold voltage distribution of a plurality of target memory cells based on the histogram.

For example, the histogram is directly taken as the threshold voltage distribution for a plurality of target memory cells.

For example, according to the shape of the histogram, an appropriate probability distribution function is selected to fit the threshold voltage distribution, and the fitted distribution function curve is taken as the threshold voltage distribution of the plurality of target memory cells. For example, the probability distribution function may include a normal distribution function, a lognormal distribution function, etc.

In some examples, after determining the threshold voltage distribution of the plurality of target memory cells, the determined threshold voltage distribution may be compared with the standard threshold voltage distribution, and according to the comparison result, it may be analyzed that whether any error exits in the target memory cells, and the reason for the error may be analyzed if any error exists.

In some examples, the memory controller 720 may implement the process of determining the threshold voltage distribution of a plurality of target memory cells according to operations 701 to 703 described above based on firmware implementation.

In examples of the present application, before determining the threshold voltage distribution of a plurality of target memory cells, the target voltage interval in which the threshold voltage of each target memory cell is located is first determined, that is, the approximate position of the threshold voltage of each target memory cell is determined. In addition, a single read operation is implemented according to a plurality of read voltages, that is, offsetting a plurality of reference read voltages in one time may measure the threshold voltage distribution more quickly. Moreover, by using the way of normal reading of memory cells, the target voltage interval which the threshold voltage distribution is determined based on is determined from a voltage obtained by offsetting the reference read voltage. The determined threshold voltage distribution has strong referential property and may be further used without later correction, for example, by comparing it with the standard threshold voltage distribution to analyze the reasons for errors.

In examples of the present disclosure, the process of determining the threshold voltage distribution of a plurality of target memory cells is achieved through a plurality of read operations, wherein each read operation is performed based on a plurality of read voltages (e.g., one set of read voltages), which facilitates improving the efficiency of determining the threshold voltage distribution of a plurality of target memory cells.

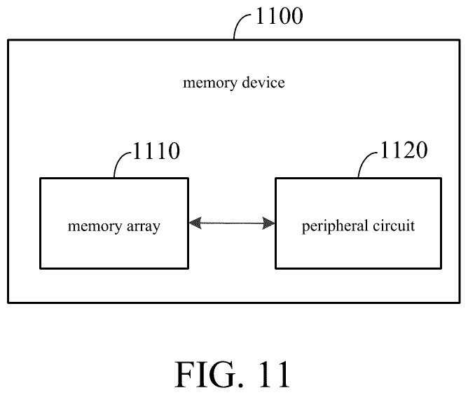

An example of the present disclosure provides a memory device, as shown in FIG. 11. The memory device 1100 includes a memory array 1110 and a peripheral circuit 1120 coupled to the memory array 1110. The memory array 1110 includes a memory cell. The memory device 1100 may be the memory device 103 shown in FIGS. 1 to 4 described above. The memory array 1110 may be the memory array 310 shown in FIG. 4 or 5 described above. The peripheral circuit 1120 may be the peripheral circuit 340 shown in FIG. 4 or 5.

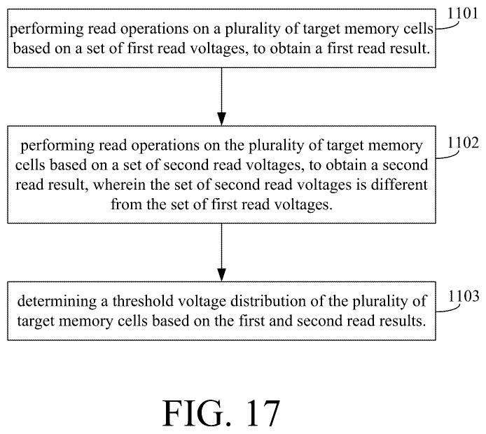

In the example of the present disclosure, the peripheral circuit 1120 is configured to perform operations 1101 to 1103 (refer to FIG. 17) as follows:

Operation 1101: performing read operations on a plurality of target memory cells based on a set of first read voltages, to obtain a first read result.

The process of the peripheral circuit 1120 obtaining the first read result may refer to the process of the memory device 710 obtaining the first read result in operation 701, and will not be repeated here.

Operation 1102: performing read operations on the plurality of target memory cells based on a set of second read voltages, to obtain a second read result, wherein the set of second read voltages is different from the set of first read voltages.

The process of the peripheral circuit 1120 obtaining the second read result may refer to the process of the memory device 710 obtaining the second read result in operation 702, and will not be repeated here.

In some examples, the memory device 1100 is coupled to a memory controller.

The peripheral circuit 1120 is configured to perform read operations on a plurality of target memory cells based on a set of first read voltages in response to receiving a read instruction sent from the memory controller, and to perform read operations on a plurality of target memory cells based on a set of second read voltages.

For example, the number of read instructions is one, and the one read instruction indicates the peripheral circuit 1120 to perform read operations on a plurality of target memory cells based on the set of first read voltages and the set of second read voltages, respectively.

For example, the read instruction includes a first read instruction and a second read instruction. The first read instruction indicates the peripheral circuit 1120 to perform read operations on a plurality of target memory cells based on the set of first read voltages. The second read instruction indicates the peripheral circuit 1120 to perform read operations on a plurality of target memory cells based on the set of second read voltages. For example, the first read instruction and the second read instruction may be sent separately by the memory controller or sent together by the memory controller.

In some examples, the set of first read voltages and the set of second read voltages are any two any two sets of read voltages in n sets of read voltages, wherein n is an integer greater than 1. The n sets of read voltages include a set of reference read voltages and (n−1) sets of offset read voltages. Different sets of offset read voltages in the (n−1) sets of offset read voltages are obtained by offsetting reference read voltages in the set of reference read voltages with different offset ways.

In some examples, an offset way corresponding to any set of offset read voltages includes an offset direction and an offset value. A plurality of sets of offset read voltages corresponding to the same offset value in (n−1) sets of offset read voltages correspond to different offset directions, and a plurality of sets of offset read voltages corresponding to the same offset direction in the (n−1) sets of offset read voltages correspond to different offset values.

In some examples, an offset direction and an offset value corresponding to the i-th set of offset read voltages in the (n−1) sets of offset read voltages are a first offset direction and a first offset value, respectively, wherein i is a positive odd number less than or equal to n−3; an offset direction and an offset value corresponding to the (i+1)th set of offset read voltages in the (n−1) sets of offset read voltages are a second offset direction and the first offset value, respectively; and an offset direction and an offset value corresponding to the (i+2)th set of offset read voltages in the (n−1) sets of offset read voltages are the first offset direction and a second offset value, respectively, wherein the first offset direction is a direction of increasing a reference read voltage in the set of reference read voltages, and the second offset direction is a direction of decreasing a reference read voltage in the set of reference read voltages, and the second offset value is greater than the first offset value.

In some examples, an offset direction and an offset value corresponding to the (n−2)th set of offset read voltages in the (n−1) sets of offset read voltages are the first offset direction and a target offset value, respectively; and an offset direction and an offset value corresponding to the (n−1)th set of offset read voltages in the (n−1) sets of offset read voltages are the second offset direction and the target offset value, respectively, wherein the target offset value is an offset value which causes an offset read voltage corresponding to a first reference read voltage to be greater than or equal to an offset read voltage corresponding to a second reference read voltage, the offset read voltage corresponding to the first reference read voltage is obtained by offsetting the first reference read voltage in the first offset direction, and the offset read voltage corresponding to the second reference read voltage is obtained by offsetting the second reference read voltage in the second offset direction; and the first reference read voltage and the second reference read voltage are two adjacent reference read voltages in the set of reference read voltages in order of magnitude, and the first reference read voltage is less than the second reference read voltage.

The relevant description of the set of first read voltages and the set of second read voltages may refer to the relevant content in operation 702, and will not be repeated here.

Operation 1103: determining a threshold voltage distribution of the plurality of target memory cells based on the first and second read results.

In the example of the present disclosure, the process of determining the threshold voltage distribution of a plurality of target memory cells based on the first and second read results is performed by the peripheral circuit 1120.

In some examples, the peripheral circuit 1120 is configured to: determine the number of target memory cells corresponding to each voltage interval in a plurality of voltage intervals based on the first and second read results, wherein the plurality of voltage intervals are voltage intervals that are determined based on the set of first read voltages and the set of second read voltages, and a threshold voltage of a target memory cell corresponding to any voltage interval is located within the any voltage interval; and determine the threshold voltage distribution of the plurality of target memory cells based on the number of target memory cells corresponding to respective voltage intervals.

In some examples, the peripheral circuit 1120 is configured to: determine a first voltage interval in which a threshold voltage of each target memory cell is located based on the set of first read voltages and the first read result; determine a second voltage interval in which the threshold voltage of each target memory cell is located based on the set of second read voltages and the second read result; determine a target voltage interval in which the threshold voltage of each target memory cell is located based on the first voltage interval and the second voltage interval, wherein an upper limit of the target voltage interval is a minimum value of an upper limit of the first voltage interval and an upper limit of the second voltage interval, and a lower limit of the target voltage interval is a maximum value of a lower limit of the first voltage interval and a lower limit of the second voltage interval; and count the number of target memory cells corresponding to each voltage interval based on the target voltage intervals in which the threshold voltages of respective target memory cells are located.

The principle of the peripheral circuit 1120 determining the threshold voltage distribution of a plurality of target memory cells based on the first and second read results is the same as the principle of the memory controller 720 determining the threshold voltage distribution of a plurality of target memory cells based on the first and second read results in operation 703, and will not be repeated here.

In some examples, for the case in which the process of determining the threshold voltage distribution of a plurality of target memory cells based on the first and second read results is performed by the peripheral circuit 1120, the peripheral circuit 1120 is further configured to send the threshold voltage distribution to the memory controller.

In the examples of the present disclosure, the process of determining the threshold voltage distribution of a plurality of target memory cells is achieved through a plurality of read operations, wherein each read operation is based on a plurality of read voltages (e.g., one set of read voltages), which facilitates improving the efficiency of determining the threshold voltage distribution of a plurality of target memory cells.

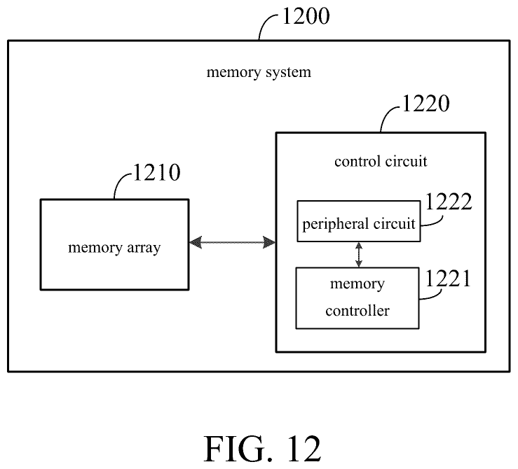

An example of the present disclosure provides a memory system, as shown in FIG. 12. The memory system 1200 includes a memory array 1210 and a control circuit 1220. The memory array 1210 includes a memory cell. The memory system 1200 may be the memory system 102 shown in FIG. 1, and the memory array 1210 may be the memory array 310 shown in FIG. 4 or 5.

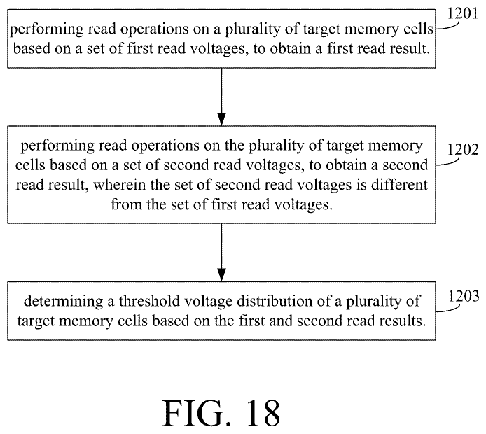

In the example of the present disclosure, the control circuit 1220 is configured to perform operations 1201 to 1203 (refer to FIG. 18) as follows:

Operation 1201: performing read operations on a plurality of target memory cells based on a set of first read voltages, to obtain a first read result.

Operation 1202: performing read operations on a plurality of target memory cells based on a set of second read voltages, to obtain a second read result, wherein the set of second read voltages is different from the set of first read voltages.

In some examples, referring to FIG. 12, the control circuit 1220 includes a memory controller 1221 and a peripheral circuit 1222. The memory controller 1221 may be the memory controller 104 shown in FIGS. 1 to 3 described above, or the memory controller 720 shown in FIG. 7. The peripheral circuit 1222 may be the peripheral circuit 340 in FIG. 4 or 5, or the peripheral circuit 1120 in FIG. 11.

In some examples, the memory controller 1221 is configured to send a read instruction to the peripheral circuit 1222. The peripheral circuit 1222 is configured to in response to receiving the read instruction sent from the memory controller 1221, perform read operations on a plurality of target memory cells based on the set of first read voltages, and perform read operations on the plurality of target memory cells based on the set of second read voltages.

The process of the control circuit 1220 performing read operations on a plurality of target memory cells based on the set of first read voltages and the set of second read voltages may refer to the relevant description in operations 701 to 702 and operations 1101 to 1102, and will not be repeated here.

In some examples, the set of first read voltages and the set of second read voltages are any two sets of read voltages in n sets of read voltages, wherein n is an integer greater than 1. The n sets of read voltages include a set of reference read voltages and (n−1) sets of offset read voltages. Different sets of offset read voltages in the (n−1) sets of offset read voltages are obtained by offsetting reference read voltages in the set of reference read voltages with different offset ways.

In some examples, an offset way corresponding to any set of offset read voltages includes an offset direction and an offset value. A plurality of sets of offset read voltages corresponding to the same offset value in (n−1) sets of offset read voltages correspond to different offset directions, and a plurality of sets of offset read voltages corresponding to the same offset direction in (n−1) sets of offset read voltages correspond to different offset values.

In some examples, an offset direction and an offset value corresponding to the i-th set of offset read voltages in the (n−1) sets of offset read voltages are a first offset direction and a first offset value, respectively, wherein i is a positive odd number less than or equal to n−3; an offset direction and an offset value corresponding to the (i+1)th set of offset read voltages in the (n−1) sets of offset read voltages are a second offset direction and the first offset value, respectively; and an offset direction and an offset value corresponding to the (i+2)th set of offset read voltages in the (n−1) sets of offset read voltages are the first offset direction and a second offset value, respectively, wherein the first offset direction is a direction of increasing a reference read voltage in the set of reference read voltages, and the second offset direction is a direction of decreasing a reference read voltage in the set of reference read voltages, and the second offset value is greater than the first offset value.

In some examples, an offset direction and an offset value corresponding to the (n−2)th set of offset read voltages in the (n−1) sets of offset read voltages are the first offset direction and a target offset value, respectively, and an offset direction and an offset value corresponding to the (n−1)th set of offset read voltages in the (n−1) sets of offset read voltages are the second offset direction and the target offset value, respectively, wherein the target offset value is an offset value which causes an offset read voltage corresponding to a first reference read voltage to be greater than or equal to an offset read voltage corresponding to a second reference read voltage, the offset read voltage corresponding to the first reference read voltage is obtained by offsetting the first reference read voltage in the first offset direction, and the offset read voltage corresponding to the second reference read voltage is obtained by offsetting the second reference read voltage in the second offset direction; and the first reference read voltage and the second reference read voltage are two adjacent reference read voltages in the set of reference read voltages in order of magnitude, and the first reference read voltage is less than the second reference read voltage.

The relevant description of the set of first read voltages and the set of second read voltages may refer to the relevant content in operation 702, and will not be repeated here.

Operation 1203: determining a threshold voltage distribution of a plurality of target memory cells based on the first and second read results.

In some examples, the control circuit 1220 is configured to: determine the number of target memory cells corresponding to each voltage interval in a plurality of voltage intervals based on the first and second read results, wherein the plurality of voltage intervals are voltage intervals that are determined based on the set of first read voltages and the set of second read voltages, and a threshold voltage of a target memory cell corresponding to any voltage interval is located within the any voltage interval; and determine the threshold voltage distribution of the plurality of target memory cells based on the number of target memory cells corresponding to respective voltage intervals.

In some examples, the control circuit 1220 is configured to: determine a first voltage interval in which a threshold voltage of each target memory cell is located based on the set of first read voltages and the first read result; determine a second voltage interval in which the threshold voltage of each target memory cell is located based on the set of second read voltages and the second read result; determine a target voltage interval in which the threshold voltage of each target memory cell is located based on the first voltage interval and the second voltage interval, wherein an upper limit of the target voltage interval is a minimum value of an upper limit of the first voltage interval and an upper limit of the second voltage interval, and a lower limit of the target voltage interval is a maximum value of a lower limit of the first voltage interval and a lower limit of the second voltage interval; and count the number of target memory cells corresponding to each voltage interval based on the target voltage intervals in which the threshold voltages of respective target memory cells are located.

In some examples, the control circuit 1220 includes a memory controller 1221 and a peripheral circuit 1222. The peripheral circuit 1222 is configured to send the first read result to the memory controller 1221 and the second read result to the memory controller 1221. The memory controller 1221 is configured to: receive the first read result and the second read result, determine the number of target memory cells corresponding to each voltage interval in a plurality of voltage intervals based on the first and second read results, and determine the threshold voltage distribution of the plurality of target memory cells based on the number of target memory cells corresponding to respective voltage intervals. The example process may refer to the relevant description in operation 703, and will not be repeated here.

In some examples, the control circuit 1220 includes a peripheral circuit 1222. The peripheral circuit 1222 is configured to: determine the number of target memory cells corresponding to each voltage interval in a plurality of voltage intervals based on the first and second read results; and determine the threshold voltage distribution of the plurality of target memory cells based on the number of target memory cells corresponding to respective voltage intervals. The example process may refer to the relevant description in operation 1103, and will not be repeated here. In some examples, the control circuit 1220 further includes a memory controller 1221, and the peripheral circuit 1222 is further configured to send the threshold voltage distribution to the memory controller 1221. The memory controller 1221 is configured to receive the threshold voltage distribution.

In some examples, the control circuit 1220 includes a memory controller 1221 and a peripheral circuit 1222. The peripheral circuit 1222 is configured to: determine the number of target memory cells corresponding to each voltage interval in a plurality of voltage intervals based on the first and second read results, and send the number of target memory cells corresponding to each voltage interval to the memory controller 1221. The memory controller 1221 is also configured to: receive the number of target memory cells corresponding to each voltage interval; and determine the threshold voltage distribution of a plurality of target memory cells based on the number of target memory cells corresponding to respective voltage intervals. In this case, the process of determining the threshold voltage distribution of a plurality of target memory cells based on the first and second read results is executed interactively by the peripheral circuit 1222 and the memory controller 1221. The principle of the peripheral circuit 1222 determining the number of target memory cells corresponding to each voltage interval based on the first and second read results is the same as the principle of the memory controller 720 determining the number of target memory cells corresponding to each voltage interval based on the first and second read results in operation 703. The implementation for the memory controller 1221 determining the threshold voltage distribution of a plurality of target memory cells based on the number of target memory cells corresponding to respective voltage intervals may refer to the relevant description in operation 703, and will not be repeated here.

In the example of the present disclosure, the process of determining the threshold voltage distribution of a plurality of target memory cells is achieved through a plurality of read operations, wherein each read operation is performed based on a plurality of read voltages (e.g., one set of read voltages), which facilitates improving the efficiency of determining the threshold voltage distribution of a plurality of target memory cells.

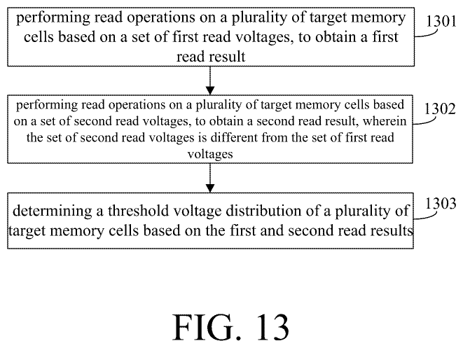

An example of the present disclosure provides a method for operating a memory system, as shown in FIG. 13. The method for operating the memory system includes operations 1301 to 1303:

Operation 1301: performing read operations on a plurality of target memory cells based on a set of first read voltages, to obtain a first read result.

Operation 1302: performing read operations on a plurality of target memory cells based on a set of second read voltages, to obtain a second read result, wherein the set of second read voltages is different from the set of first read voltages.

In some examples, the set of first read voltages and the set of second read voltages are any two sets of read voltages in n sets of read voltages, wherein n is an integer greater than 1, wherein the n sets of read voltages include a set of reference read voltages and (n−1) sets of offset read voltages. Different sets of offset read voltages in the (n−1) sets of offset read voltages are obtained by offsetting reference read voltages in the set of reference read voltages with different offset ways.

In some examples, an offset way corresponding to any set of offset read voltages includes an offset direction and an offset value. A plurality of sets of offset read voltages corresponding to the same offset value in (n−1) sets of offset read voltages correspond to different offset directions, and a plurality of sets of offset read voltages corresponding to the same offset direction in (n−1) sets of offset read voltages correspond to different offset values.

In some examples, an offset direction and an offset value corresponding to the i-th set of offset read voltages in the (n−1) sets of offset read voltages are a first offset direction and a first offset value, respectively, wherein i is a positive odd number less than or equal to n−3; an offset direction and an offset value corresponding to the (i+1)th set of offset read voltages in the (n−1) sets of offset read voltages are a second offset direction and the first offset value, respectively; and an offset direction and an offset value corresponding to the (i+2)th set of offset read voltages in the (n−1) sets of offset read voltages are the first offset direction and a second offset value, respectively, wherein the first offset direction is a direction of increasing a reference read voltage in the set of reference read voltages, and the second offset direction is a direction of decreasing a reference read voltage in the set of reference read voltages, and the second offset value is greater than the first offset value.

In some examples, an offset direction and an offset value corresponding to the (n−2)th set of offset read voltages in the (n−1) sets of offset read voltages are the first offset direction and a target offset value, respectively, and an offset direction and an offset value corresponding to the (n−1)th set of offset read voltages in the (n−1) sets of offset read voltages are the second offset direction and the target offset value, respectively, wherein the target offset value is an offset value which causes an offset read voltage corresponding to a first reference read voltage to be greater than or equal to an offset read voltage corresponding to a second reference read voltage, the offset read voltage corresponding to the first reference read voltage is obtained by offsetting the first reference read voltage in the first offset direction, and the offset read voltage corresponding to the second reference read voltage is obtained by offsetting the second reference read voltage in the second offset direction; and the first reference read voltage and the second reference read voltage are two adjacent reference read voltages in the set of reference read voltages in order of magnitude, and the first reference read voltage is less than the second reference read voltage.

Operation 1303: determining a threshold voltage distribution of a plurality of target memory cells based on the first and second read results.

In some examples, determining the threshold voltage distribution of a plurality of target memory cells based on the first and second read results includes: determining the number of target memory cells corresponding to each voltage interval in a plurality of voltage intervals based on the first and second read results, wherein the plurality of voltage intervals are voltage intervals that are determined based on the set of first read voltages and the set of second read voltages, and a threshold voltage of a target memory cell corresponding to any voltage interval is located within the any voltage interval; and determining the threshold voltage distribution of the plurality of target memory cells based on the number of target memory cells corresponding to respective voltage intervals.

In some examples, determining the number of target memory cells corresponding to each voltage interval in a plurality of voltage intervals based on the first and second read results includes: determining a first voltage interval in which a threshold voltage of each target memory cell is located based on the set of first read voltages and the first read result; determining a second voltage interval in which the threshold voltage of each target memory cell is located based on the set of second read voltages and the second read result; determining a target voltage interval in which the threshold voltage of each target memory cell is located based on the first voltage interval and the second voltage interval, wherein an upper limit of the target voltage interval is a minimum value of an upper limit of the first voltage interval and an upper limit of the second voltage interval, and a lower limit of the target voltage interval is a maximum value of a lower limit of the first voltage interval and a lower limit of the second voltage interval; and counting the number of target memory cells corresponding to respective voltage intervals based on the target voltage intervals in which the threshold voltages of respective target memory cells are located.

For example, a memory system includes a memory array and a control circuit. The memory array includes a memory cell, and the control circuit is to perform the method of operating the memory system described above.

The description of examples of the operation method of the memory system above has similar beneficial effects as the hardware example of the memory system described in FIG. 12. For technical details not disclosed in examples of the operation method of the memory system above, please refer to the description of the hardware example of the memory system described in FIG. 12 for understanding, which will not be repeated here.

An example of the present disclosure provides a non-transitory computer-readable storage medium storing at least one computer program. The at least one computer program is loaded and executed by a control circuit in a memory system to implement the operation method of the memory system. In some examples, computer programs in the non-transitory computer-readable storage medium may also be referred to as firmware.

In some examples, non-transitory computer-readable storage media may be magnetic random access memory (FRAM), read-only memory (ROM), programmable read-only memory (PROM), erasable programmable read-only memory (EPROM), electrically erasable programmable read-only memory (EEPROM), flash memory, magnetic surface storage, optical disc, or compact disc read only memory (CD-ROM) and other storage media, or include combinations of the aforementioned storage media.

In some examples, computer programs may take the form of programs, software, software modules, scripts, or code, written in any form of programming language (including compiled or interpreted languages, or declarative or procedural languages), and may be deployed in any form, including as standalone programs or as modules, components, subroutines, or other units suitable for use in computing environments.

It should be understood that the term ‘a plurality of’ mentioned herein refers to two or more. The term ‘and/or’ describes the association relationship between related objects, indicating that there may be three types of relationships. For example, A and/or B may represent: A alone, A and B, and B alone. The character ‘/’ generally indicates that the associated objects before and after have an ‘or’ relationship.

Examples of the present disclosure provide a memory system and operating method thereof, a memory device, and a storage medium. The technical solution is as follows:

In one aspect, examples of the present disclosure provide a memory system. The memory system comprises a memory device and a memory controller coupled to the memory device, wherein the memory device comprises a memory cell, and the memory controller is configured to:
send a first read instruction to the memory device, wherein the first read instruction indicates to the memory device to perform read operations on a plurality of target memory cells based on a set of first read voltages, to obtain a first read result;
send a second read instruction to the memory device, wherein the second read instruction indicates to the memory device to perform read operations on the plurality of target memory cells based on a set of second read voltages, to obtain a second read result, and the set of second read voltages is different from the set of first read voltages; and
determine a threshold voltage distribution of the plurality of target memory cells based on the first and second read results.

In some examples, the set of first read voltages and the set of second read voltages are any two sets of read voltages in n sets of read voltages, wherein n is an integer greater than 1; and
the n sets of read voltages include a set of reference read voltages and (n−1) sets of offset read voltages, and different sets of offset read voltages in the (n−1) sets of offset read voltages are obtained by offsetting reference read voltages in the set of reference read voltages with different offset ways.

In some examples, an offset way corresponding to any set of offset read voltages includes an offset direction and an offset value; and
a plurality of sets of offset read voltages corresponding to the same offset value in the (n−1) sets of offset read voltages correspond to different offset directions, and a plurality of sets of offset read voltages corresponding to the same offset direction in the (n−1) sets of offset read voltages correspond to different offset values.

In some examples, an offset direction and an offset value corresponding to the i-th set of offset read voltages in the (n−1) sets of offset read voltages are a first offset direction and a first offset value, respectively, wherein i is a positive odd number less than or equal to n−3;

an offset direction and an offset value corresponding to the (i+1)th set of offset read voltages in the (n−1) sets of offset read voltages are a second offset direction and the first offset value, respectively; and
an offset direction and an offset value corresponding to the (i+2)th set of offset read voltages in the (n−1) sets of offset read voltages are the first offset direction and a second offset value, respectively;
wherein the first offset direction is a direction of increasing a reference read voltage in the set of reference read voltages, and the second offset direction is a direction of decreasing a reference read voltage in the set of reference read voltages, and the second offset value is greater than the first offset value.

In some examples, an offset direction and an offset value corresponding to the (n−2)th set of offset read voltages in the (n−1) sets of offset read voltages are the first offset direction and a target offset value, respectively, and an offset direction and an offset value corresponding to the (n−1)th set of offset read voltages in the (n−1) sets of offset read voltages are the second offset direction and the target offset value, respectively; and
wherein the target offset value is an offset value which causes an offset read voltage corresponding to a first reference read voltage to be greater than or equal to an offset read voltage corresponding to a second reference read voltage, the offset read voltage corresponding to the first reference read voltage is obtained by offsetting the first reference read voltage in the first offset direction, and the offset read voltage corresponding to the second reference read voltage is obtained by offsetting the second reference read voltage in the second offset direction; and
the first reference read voltage and the second reference read voltage are two adjacent reference read voltages in the set of reference read voltages in order of magnitude, and the first reference read voltage is less than the second reference read voltage.

In some examples, the memory controller is configured to:
determine the number of target memory cells corresponding to each voltage interval in a plurality of voltage intervals based on the first and second read results, wherein the plurality of voltage intervals are voltage intervals that are determined from the set of first read voltages and the set of second read voltages, and a threshold voltage of a target memory cell corresponding to any voltage interval is located within the any voltage interval; and
determine the threshold voltage distribution of the plurality of target memory cells based on the number of target memory cells corresponding to respective voltage intervals.

In some examples, the memory controller is configured to:
determine a first voltage interval in which a threshold voltage of each target memory cell is located based on the set of first read voltages and the first read result;
determine a second voltage interval in which the threshold voltage of each target memory cell is located based on the set of second read voltages and the second read result;
determine a target voltage interval in which the threshold voltage of each target memory cell is located based on the first voltage interval and the second voltage interval, wherein an upper limit of the target voltage interval is a minimum value of an upper limit of the first voltage interval and an upper limit of the second voltage interval, and a lower limit of the target voltage interval is a maximum value of a lower limit of the first voltage interval and a lower limit of the second voltage interval; and
count the number of target memory cells corresponding to each voltage interval based on the target voltage intervals in which the threshold voltages of respective target memory cells are located.

In another aspect, examples of the present disclosure provide a memory device. The memory device comprises a memory array and a peripheral circuit coupled to the memory array, wherein the memory array comprises a memory cell, and the peripheral circuit is configured to:
perform read operations on a plurality of target memory cells based on a set of first read voltages, to obtain a first read result;
perform read operations on the plurality of target memory cells based on a set of second read voltages, to obtain a second read result, wherein the set of second read voltages is different from the set of first read voltages; and
determine a threshold voltage distribution of the plurality of target memory cells based on the first and second read results.

In some examples, the memory device is coupled to a memory controller, and the peripheral circuit is configured to:
in response to receiving a read instruction sent from the memory controller, perform read operations on the plurality of target memory cells based on the set of first read voltages, and perform read operations on the plurality of target memory cells based on the set of second read voltages.

In some examples, the peripheral circuit is further configured to send the threshold voltage distribution to the memory controller.

In some examples, the peripheral circuit is configured to:
determine the number of target memory cells corresponding to each voltage interval in a plurality of voltage intervals based on the first and second read results, wherein the plurality of voltage intervals are voltage intervals that are determined from the set of first read voltages and the set of second read voltages, and a threshold voltage of a target memory cell corresponding to any voltage interval is located within the any voltage interval; and
determine the threshold voltage distribution of the plurality of target memory cells based on the number of target memory cells corresponding to respective voltage intervals.

In some examples, the peripheral circuit is configured to:
determine a first voltage interval in which a threshold voltage of each target memory cell is located based on the set of first read voltages and the first read result;
determine a second voltage interval in which the threshold voltage of each target memory cell is located based on the set of second read voltages and the second read result;
determine a target voltage interval in which the threshold voltage of each target memory cell is located based on the first voltage interval and the second voltage interval, wherein an upper limit of the target voltage interval is a minimum value of an upper limit of the first voltage interval and an upper limit of the second voltage interval, and a lower limit of the target voltage interval is a maximum value of a lower limit of the first voltage interval and a lower limit of the second voltage interval; and
count the number of target memory cells corresponding to each voltage interval based on the target voltage intervals in which the threshold voltages of respective target memory cells are located.

In another aspect, examples of the present disclosure provide a memory system. The memory system comprises a control circuit and a memory array, wherein the memory array comprises a memory cell, and the control circuit is configured to:
perform read operations on a plurality of target memory cells based on a set of first read voltages, to obtain a first read result;
perform read operations on the plurality of target memory cells based on a set of second read voltages, to obtain a second read result, wherein the set of second read voltages is different from the set of first read voltages; and
determine a threshold voltage distribution of the plurality of target memory cells based on the first and second read results.

In some examples, the control circuit is configured to:
determine the number of target memory cells corresponding to each voltage interval in a plurality of voltage intervals based on the first and second read results, wherein the plurality of voltage intervals are voltage intervals that are determined from the set of first read voltages and the set of second read voltages, and a threshold voltage of a target memory cell corresponding to any voltage interval is located within the any voltage interval; and
determine the threshold voltage distribution of the plurality of target memory cells based on the number of target memory cells corresponding to respective voltage intervals.

In some examples, the control circuit is configured to:
determine a first voltage interval in which a threshold voltage of each target memory cell is located based on the set of first read voltages and the first read result;
determine a second voltage interval in which the threshold voltage of each target memory cell is located based on the set of second read voltages and the second read result;
determine a target voltage interval in which the threshold voltage of each target memory cell is located based on the first voltage interval and the second voltage interval, wherein an upper limit of the target voltage interval is a minimum value of an upper limit of the first voltage interval and an upper limit of the second voltage interval, and a lower limit of the target voltage interval is a maximum value of a lower limit of the first voltage interval and a lower limit of the second voltage interval; and
count the number of target memory cells corresponding to each voltage interval based on the target voltage intervals in which the threshold voltages of respective target memory cells are located.

In some examples, the control circuit comprises a memory controller and a peripheral circuit;
wherein the peripheral circuit is configured to send the first read result to the memory controller and the second read result to the memory controller; and
the memory controller is configured to receive the first read result and the second read result, determine the number of target memory cells corresponding to each voltage interval in a plurality of voltage intervals based on the first and second read results, and determine the threshold voltage distribution of the plurality of target memory cells based on the number of target memory cells corresponding to respective voltage intervals.

In some examples, the control circuit comprises a memory controller and a peripheral circuit;
wherein the peripheral circuit is configured to determine the number of target memory cells corresponding to each voltage interval in a plurality of voltage intervals based on the first and second read results, and send the number of target memory cells corresponding to each voltage interval to the memory controller; and
the memory controller is further configured to receive the number of target memory cells corresponding to each voltage interval, and determine the threshold voltage distribution of the plurality of target memory cells based on the number of target memory cells corresponding to respective voltage intervals.

In some examples, the control circuit comprises a peripheral circuit;
wherein the peripheral circuit is configured to determine the number of target memory cells corresponding to each voltage interval in a plurality of voltage intervals based on the first and second read results, and determine the threshold voltage distribution of the plurality of target memory cells based on the number of target memory cells corresponding to respective voltage intervals.

In some examples, the control circuit further comprises a memory controller;
wherein the memory controller is configured to send a read instruction to the peripheral circuit; and
the peripheral circuit is configured to: in response to receiving the read instruction sent from the memory controller, perform read operations on the plurality of target memory cells based on the set of first read voltages, and perform read operations on the plurality of target memory cells based on the set of second read voltages; and send the threshold voltage distribution to the memory controller.

In another aspect, examples of the present disclosure provide a method for operating a memory system. The method comprises:
performing read operations on a plurality of target memory cells based on a set of first read voltages, to obtain a first read result;
performing read operations on the plurality of target memory cells based on a set of second read voltages, to obtain a second read result, wherein the set of second read voltages is different from the set of first read voltages; and
determining a threshold voltage distribution of the plurality of target memory cells based on the first and second read results.

In some examples, the set of first read voltages and the set of second read voltages are any two sets of read voltages in n sets of read voltages, wherein n is an integer greater than 1; and
the n sets of read voltages include a set of reference read voltages and (n−1) sets of offset read voltages, and different sets of offset read voltages in the (n−1) sets of offset read voltages are obtained by offsetting reference read voltages in the set of reference read voltages with different offset ways.

In some examples, an offset way corresponding to any set of offset read voltages includes an offset direction and an offset value; and
a plurality of sets of offset read voltages corresponding to the same offset value in the (n−1) sets of offset read voltages correspond to different offset directions, and a plurality of sets of offset read voltages corresponding to the same offset direction in the (n−1) sets of offset read voltages correspond to different offset values.

In some examples, an offset direction and an offset value corresponding to the i-th set of offset read voltages in the (n−1) sets of offset read voltages are a first offset direction and a first offset value, respectively, wherein i is a positive odd number less than or equal to n−3;
an offset direction and an offset value corresponding to the (i+1)th set of offset read voltages in the (n−1) sets of offset read voltages are a second offset direction and the first offset value, respectively; and
an offset direction and an offset value corresponding to the (i+2)th set of offset read voltages in the (n−1) sets of offset read voltages are the first offset direction and a second offset value, respectively;
wherein the first offset direction is a direction of increasing a reference read voltage in the set of reference read voltages, and the second offset direction is a direction of decreasing a reference read voltage in the set of reference read voltages, and the second offset value is greater than the first offset value.

In some examples, an offset direction and an offset value corresponding to the (n−2)th set of offset read voltages in the (n−1) sets of offset read voltages are the first offset direction and a target offset value, respectively, and an offset direction and an offset value corresponding to the (n−1)th set of offset read voltages in the (n−1) sets of offset read voltages are the second offset direction and the target offset value, respectively; and
wherein the target offset value is an offset value which causes an offset read voltage corresponding to a first reference read voltage to be greater than or equal to an offset read voltage corresponding to a second reference read voltage, the offset read voltage corresponding to the first reference read voltage is obtained by offsetting the first reference read voltage in the first offset direction, and the offset read voltage corresponding to the second reference read voltage is obtained by offsetting the second reference read voltage in the second offset direction; and
the first reference read voltage and the second reference read voltage are two adjacent reference read voltages in the set of reference read voltages in order of magnitude, and the first reference read voltage is less than the second reference read voltage.

In some examples, determining the threshold voltage distribution of the plurality of target memory cells based on the first and second read results comprises:
determining the number of target memory cells corresponding to each voltage interval in a plurality of voltage intervals based on the first and second read results, wherein the plurality of voltage intervals are voltage intervals that are determined from the set of first read voltages and the set of second read voltages, and a threshold voltage of a target memory cell corresponding to any voltage interval is located within the any voltage interval; and
determining the threshold voltage distribution of the plurality of target memory cells based on the number of target memory cells corresponding to respective voltage intervals.

In some examples, determining the number of target memory cells corresponding to each voltage interval in a plurality of voltage intervals based on the first and second read results comprises:
determining a first voltage interval in which a threshold voltage of each target memory cell is located based on the set of first read voltages and the first read result;
determining a second voltage interval in which the threshold voltage of each target memory cell is located based on the set of second read voltages and the second read result;
determining a target voltage interval in which the threshold voltage of each target memory cell is located based on the first voltage interval and the second voltage interval, wherein an upper limit of the target voltage interval is a minimum value of an upper limit of the first voltage interval and an upper limit of the second voltage interval, and a lower limit of the target voltage interval is a maximum value of a lower limit of the first voltage interval and a lower limit of the second voltage interval; and
counting the number of target memory cells corresponding to each voltage interval based on the target voltage intervals in which the threshold voltages of respective target memory cells are located.

In another aspect, examples of the present disclosure provide a non-transitory computer-readable storage medium storing at least one computer program. The at least one computer program is loaded and executed by a control circuit in a memory system to implement any of methods for operating the memory system described above.

The above are only examples of the present disclosure and are not intended to limit the present disclosure. Any modifications, equivalent substitutions, improvements, etc. made within the principles of the present disclosure shall be included in the scope of the present disclosure.

What is claimed is:

1. A memory system, comprising:
a memory device comprising a memory cell; and
a memory controller coupled to the memory device and configured to:
send a first read instruction to the memory device, wherein the first read instruction indicates to the memory device to perform first read operations on a plurality of target memory cells based on a set of first read voltages, the first read operations to obtain a first read result;
send a second read instruction to the memory device, wherein the second read instruction indicates to the memory device to perform second read operations on the plurality of target memory cells based on a set of second read voltages, the second read operations to obtain a second read result, wherein the set of second read voltages is different from the set of first read voltages; and
determine a threshold voltage distribution of the plurality of target memory cells based on the first and second read results.

2. The memory system of claim 1, wherein:
the set of first read voltages and the set of second read voltages are in n sets of read voltages, wherein n is an integer greater than 1; and
the n sets of read voltages include a set of reference read voltages and (n−1) sets of offset read voltages, and different sets of offset read voltages in the (n−1) sets of offset read voltages are obtained by offsetting ones of the reference read voltages in the set of reference read voltages with different offset ways.

3. The memory system of claim 2, wherein:
an offset way corresponding to any of the (n−1) sets of offset read voltages includes an offset direction and an offset value; and
first ones of the (n−1) sets of offset read voltages corresponding to a same offset value correspond to different offset directions, and second ones of the (n−1) sets of offset read voltages corresponding to a same offset direction correspond to different offset values.

4. The memory system of claim 3, wherein:
an offset direction and an offset value corresponding to an i-th set of offset read voltages in the (n−1) sets of offset read voltages are a first offset direction and a first offset value, respectively, wherein i is a positive odd number less than or equal to n−3;
an offset direction and an offset value corresponding to an (i+1)th set of offset read voltages in the (n−1) sets of offset read voltages are a second offset direction and the first offset value, respectively;
an offset direction and an offset value corresponding to an (i+2)th set of offset read voltages in the (n−1) sets of offset read voltages are the first offset direction and a second offset value, respectively; and
the first offset direction is a direction of increasing a first reference read voltage in the set of reference read voltages, and the second offset direction is a direction of decreasing a second reference read voltage in the set of reference read voltages, and the second offset value is greater than the first offset value.

5. The memory system of claim 4, wherein:
an offset direction and an offset value corresponding to an (n−2)th set of offset read voltages in the (n−1) sets of offset read voltages are the first offset direction and a target offset value, respectively, and an offset direction and an offset value corresponding to an (n−1)th set of offset read voltages in the (n−1) sets of offset read voltages are the second offset direction and the target offset value, respectively;
the target offset value causes a first offset read voltage corresponding to the first reference read voltage to be greater than or equal to a second offset read voltage corresponding to the second reference read voltage, the first offset read voltage is obtained by offsetting the first reference read voltage in the first offset direction, and the second offset read voltage is obtained by offsetting the second reference read voltage in the second offset direction; and
the first reference read voltage and the second reference read voltage are adjacent one another in the set of reference read voltages in order of magnitude, and the first reference read voltage is less than the second reference read voltage.

6. The memory system of claim 1, wherein the memory controller is configured to:
determine a number of target memory cells corresponding to a first voltage interval in a plurality of voltage intervals based on the first and second read results, wherein the plurality of voltage intervals are determined from the set of first read voltages and the set of second read voltages, and a threshold voltage of a target memory cell corresponding to the first voltage interval of the voltage intervals is located within the first voltage interval; and
determine the threshold voltage distribution of the plurality of target memory cells based on the number of target memory cells corresponding to the first voltage interval.

7. The memory system of claim 6, wherein the memory controller is configured to:
determine the first voltage interval in which the threshold voltage of the target memory cell is located based on the set of first read voltages and the first read result;
determine a second voltage interval in which the threshold voltage of the target memory cell is located based on the set of second read voltages and the second read result;
determine a target voltage interval in which the threshold voltage of the target memory cell is located based on the first voltage interval and the second voltage interval, wherein an upper limit of the target voltage interval is a minimum value of an upper limit of the first voltage interval and an upper limit of the second voltage interval, and a lower limit of the target voltage interval is a maximum value of a lower limit of the first voltage interval and a lower limit of the second voltage interval; and
count the number of target memory cells corresponding to the first voltage interval based on the target voltage interval in which the threshold voltage of the target memory cell is located.

8. A memory system, comprising:
a memory array comprising a memory cell, and
a control circuit configured to:
perform first read operations on a plurality of target memory cells based on a set of first read voltages, the first read operations to obtain a first read result;
perform second read operations on the plurality of target memory cells based on a set of second read voltages, the second read operations to obtain a second read result, wherein the set of second read voltages is different from the set of first read voltages; and
determine a threshold voltage distribution of the plurality of target memory cells based on the first and second read results.

9. The memory system of claim 8, wherein the control circuit is configured to:
determine a number of target memory cells corresponding to a first voltage interval in a plurality of voltage intervals based on the first and second read results, wherein the plurality of voltage intervals are determined from the set of first read voltages and the set of second read voltages, and a threshold voltage of a target memory cell corresponding to the first voltage interval is located within the first voltage interval; and
determine the threshold voltage distribution of the plurality of target memory cells based on the number of target memory cells corresponding to the first voltage interval.

10. The memory system of claim 9, wherein the control circuit is configured to:
determine the first voltage interval in which the threshold voltage of the target memory cell is located based on the set of first read voltages and the first read result;
determine a second voltage interval in which the threshold voltage of the target memory cell is located based on the set of second read voltages and the second read result;
determine a target voltage interval in which the threshold voltage of the target memory cell is located based on the first voltage interval and the second voltage interval, wherein an upper limit of the target voltage interval is a minimum value of an upper limit of the first voltage interval and an upper limit of the second voltage interval, and a lower limit of the target voltage interval is a maximum value of a lower limit of the first voltage interval and a lower limit of the second voltage interval; and
count the number of target memory cells corresponding to the first voltage interval based on the target voltage interval in which the threshold voltage of the target memory cell is located.

11. The memory system of claim 9, wherein the control circuit comprises a memory controller and a peripheral circuit, wherein:
the peripheral circuit is configured to send the first read result and the second read result to the memory controller; and
the memory controller is configured to:
receive the first read result and the second read result;
determine the number of target memory cells corresponding to the first voltage interval in the plurality of voltage intervals based on the first and second read results; and
determine the threshold voltage distribution of the plurality of target memory cells based on the number of target memory cells corresponding to the first voltage interval.

12. The memory system of claim 9, wherein the control circuit comprises a memory controller and a peripheral circuit, wherein:
the peripheral circuit is configured to determine the number of target memory cells corresponding to the first voltage interval in the plurality of voltage intervals based on the first and second read results, and send the number of target memory cells to the memory controller; and
the memory controller is configured to:
receive the number of target memory cells; and
determine the threshold voltage distribution of the plurality of target memory cells based on the number of target memory cells corresponding to the first voltage interval.

13. The memory system of claim 9, wherein the control circuit comprises a peripheral circuit configured to:
determine the number of target memory cells corresponding to the first voltage interval in the plurality of voltage intervals based on the first and second read results; and
determine the threshold voltage distribution of the plurality of target memory cells based on the number of target memory cells corresponding to the first voltage interval.

14. A method for operating a memory system, the method comprising:
performing first read operations on a plurality of target memory cells based on a set of first read voltages, the first read operations to obtain a first read result;
performing second read operations on the plurality of target memory cells based on a set of second read voltages, the second read operations to obtain a second read result, wherein the set of second read voltages is different from the set of first read voltages; and
determining a threshold voltage distribution of the plurality of target memory cells based on the first and second read results.

15. The method of claim 14, wherein the set of first read voltages and the set of second read voltages are in n sets of read voltages, wherein n is an integer greater than 1; and
the n sets of read voltages include a set of reference read voltages and (n−1) sets of offset read voltages, and different sets of offset read voltages in the (n−1) sets of offset read voltages are obtained by offsetting ones of the reference read voltages in the set of reference read voltages with different offset ways.

16. The method of claim 15, wherein:
an offset way corresponding to any of the (n−1) sets of offset read voltages includes an offset direction and an offset value; and
first ones of the (n−1) sets of offset read voltages corresponding to a same offset value correspond to different offset directions, and second ones of the (n−1) sets of offset read voltages corresponding to a same offset direction correspond to different offset values.

17. The method of claim 16, wherein:
an offset direction and an offset value corresponding to an i-th set of offset read voltages in the (n−1) sets of offset read voltages are a first offset direction and a first offset value, respectively, wherein i is a positive odd number less than or equal to n−3;
an offset direction and an offset value corresponding to an (i+1)th set of offset read voltages in the (n−1) sets of offset read voltages are a second offset direction and the first offset value, respectively;
an offset direction and an offset value corresponding to an (i+2)th set of offset read voltages in the (n−1) sets of offset read voltages are the first offset direction and a second offset value, respectively; and
the first offset direction is a direction of increasing a first reference read voltage in the set of reference read voltages, and the second offset direction is a direction of decreasing a second reference read voltage in the set of reference read voltages, and the second offset value is greater than the first offset value.

18. The method of claim 17, wherein:
an offset direction and an offset value corresponding to an (n−2)th set of offset read voltages in the (n−1) sets of offset read voltages are the first offset direction and a target offset value, respectively, and an offset direction and an offset value corresponding to an (n−1)th set of offset read voltages in the (n−1) sets of offset read voltages are the second offset direction and the target offset value, respectively;
the target offset value causes a first offset read voltage corresponding to the first reference read voltage to be greater than or equal to a second offset read voltage corresponding to the second reference read voltage, the first offset read voltage is obtained by offsetting the first reference read voltage in the first offset direction, and the second offset read voltage is obtained by offsetting the second reference read voltage in the second offset direction; and
the first reference read voltage and the second reference read voltage are adjacent one another in the set of reference read voltages in order of magnitude, and the first reference read voltage is less than the second reference read voltage.

19. The method of claim 14, wherein the determining of the threshold voltage distribution of the plurality of target memory cells based on the first and second read results comprises:
determining a number of target memory cells corresponding to a first voltage interval in a plurality of voltage intervals based on the first and second read results, wherein the plurality of voltage intervals are determined from the set of first read voltages and the set of second read voltages, and a threshold voltage of a target memory cell corresponding to the first voltage interval of the voltage intervals is located within the first voltage interval; and
determining the threshold voltage distribution of the plurality of target memory cells based on the number of target memory cells corresponding to the first voltage interval.

20. The method of claim 19, wherein the determining of the number of target memory cells corresponding to the first voltage interval in the plurality of voltage intervals based on the first and second read results comprises:
determining the first voltage interval in which the threshold voltage of the target memory cell is located based on the set of first read voltages and the first read result;
determining a second voltage interval in which the threshold voltage of the target memory cell is located based on the set of second read voltages and the second read result;
determining a target voltage interval in which the threshold voltage of the target memory cell is located based on the first voltage interval and the second voltage interval, wherein an upper limit of the target voltage interval is a minimum value of an upper limit of the first voltage interval and an upper limit of the second voltage interval, and a lower limit of the target voltage interval is a maximum value of a lower limit of the first voltage interval and a lower limit of the second voltage interval; and
counting the number of target memory cells corresponding to the first voltage interval based on the target voltage interval in which the threshold voltage of the target memory cell is located.
